(19) United States
(12) Patent Application Publication
(10) Pub. No.: US 2012/0299605 A1
(43) Pub. Date: Nov. 29, 2012

(54) OCCUPANT DETECTION SENSOR AND MANUFACTURING METHOD OF THE SAME

(75) Inventors: Asei Wakabayashi, Kariya-city (JP); Takashi Inoue, Kariya-city (JP); Kouji Ootaka, Toyohashi-city (JP)

(73) Assignee: DENSO CORPORATION, Kariya-city, (JP)

(21) Appl. No.: 13/477,466

(22) Filed: May 22, 2012

(30) Foreign Application Priority Data
May 25, 2011 (JP) 2011-116860
Mar. 15, 2012 (JP) 2012-058907

(51) Int. Cl. G01R 27/26; H01R 43/00

(52) U.S. Cl. 324/679; 29/825

(57) ABSTRACT

An occupant detection sensor for detecting an occupant seating state on a seat comprises: a contact pressure sensor section including a pair of opposed electrodes arranged parallel to a seating face part of the seat; an electrostatic sensor section including a main electrode arranged parallel to the seating face part of the seat and a guard electrode arranged between the main electrode and a seat frame, the guard electrode and the main electrode having a same electric potential; a capacitance measuring section for measuring a first capacitance between the opposed electrodes and a second capacitance between the main electrode and ground; and an occupant distinguishing section for distinguishing a seating state of the occupant based on the first capacitance and the second capacitance.

### CROSS REFERENCE TO RELATED APPLICATION

The present application is based on and claims priority to Japanese Patent Applications No. 2011-116860 filed on May 25, 2011 and No. 2012-58907 filed on Mar. 15, 2012, disclosures of which are incorporated herein by reference.

### TECHNICAL FIELD

The present disclosure relates to an occupant detection sensor for detecting a state of an occupant seated on a seat and a manufacturing method of the same.

### BACKGROUND

Patent Document 1 discloses a technique for an occupant detection system to minimize a false detection caused by a disturbance such as a wet seat. In this occupant detection system, an electrostatic sensor for measuring a short range capacitance and an electrostatic sensor for measuring a long range capacitance are provided in a seat of a vehicle. The occupant detection system detects an occupant based on output signals from both sensors.

Further, Patent Document 2 discloses a technique for a capacitive occupant detection sensor to distinguish an adult of small build from an adult of large build. This capacitive occupant detection sensor includes a floating electrode, which is sandwiched between cushion members and is in an electrically floating state. The capacitive occupant detection sensor detects an occupant based on both of an occupant capacitance and a floating capacitance. The occupant capacitance is generated between an electrostatic sensor mat and an occupant. The floating capacitance is generated between the electrostatic sensor mat and the floating electrode.
Patent Document JP 2006-281990A1 corresponding to US 2006/0219460A1
Patent Document 2: JP 2011-075405A1 corresponding to US 2011/0074447A1

The inventors of the present application have found the following.

Although application of the technique of Patent Document 1 may minimize a false detection caused by a disturbance, an adult of small build cannot be distinguished from an adult of large build. On the other hand, although application of the technique of Patent Document 2 may allow an adult of small build to be distinguished from an adult of large build, a false detection caused by a disturbance cannot be minimized.

A structure for minimizing the false detection caused by a disturbance and for distinguish an adult of small build from an adult of large build may be provided with: an electrostatic sensor for measuring a short range capacitance; an electrostatic sensor for measuring a long range capacitance; and a floating electrode (sensor) for measuring a floating capacitance. According to Patent Document 2, the floating electrode needs to be formed in a layer different from a layer having a main electrode and a sub electrode. Further, a cushion member needs to be further formed between the floating electrode and the main electrode. Thus, the above structure increases manufacturing processes and hence requires a large amount of time for the manufacturing processes. Still further, according to Patent Document 2, urethane foam is used for the cushion member. When a man is seated for a long time or a load is applied for a long time or by aging degradation, the cushion member is deformed. When the cushion is deformed in this way, the floating capacitance varies and it becomes impossible to correctly distinguish an adult of small build from an adult of large build.

### SUMMARY

In view of the foregoing, it is an object of the present disclosure to provide an occupant detection sensor and a manufacturing method of the same.

According to a first example of the present disclosure, an occupant detection sensor for detecting a seating state of an occupant on a seat is provided. The occupant detection sensor comprises a contact pressure sensor section, an electrostatic sensor section, a capacitance measuring section, and an occupant distinguishing section. The contact pressure sensor section includes one or more pairs of opposed electrodes arranged approximately parallel to a seating face part of the seat. The pair of opposed electrodes is opposed to each other with a predetermined interval therebetween. The electrostatic sensor section includes a main electrode arranged approximately parallel to the seating face part of the seat and a guard electrode arranged between the main electrode and a seat frame. The guard electrode and the main electrode having a same electric potential. The capacitance measuring section measures a first capacitance generated between the opposed electrodes and a second capacitance generated between the main electrode and ground. The occupant distinguishing section distinguishes the seating state of the occupant based on the first capacitance and the second capacitance.

According to a first example of the present disclosure, a method of manufacturing an occupant detection sensor which detects a seating state of an occupant on a seat is provided. The method comprises: forming an insulating film, which is to be on a facing surface of either or both of a pair of opposed electrodes which are opposed to each other with a predetermined interval therebetween so that the opposed electrodes, respectively, have the facing surfaces, which face each other; making a hole at a predetermined position in an insulating planar member; forming a main electrode and one of the opposed electrodes, wherein the main electrode is to be approximately parallel to the seating face part of the seat; forming a guard electrode and the other of the opposed electrodes, wherein the guard electrode is to be between the seating face part and a seat frame; covering the main electrode and the one of the opposed electrodes with a first covering member; and covering the guard electrode and the other of the opposed electrodes with a second covering member.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a schematic view illustrating an occupant detection sensor;

FIGS. 2A to 2C are schematic views illustrating a first construction example of a sensor mat;

FIGS. 3A to 3E3 are section views illustrating a first manufacturing method of a sensor mat;

FIGS. 4A and 4B are section views illustrating how capacitance varies;

FIGS. 5A and 5B are graphs illustrating impedance components;

FIG. 6 is a flowchart illustrating an occupant distinguishing process;

FIG. 7 is a diagram illustrating switching in obtaining a capacitance component and a resistance component;

FIG. 8 is a flowchart illustrating an adult distinguishing process;

FIG. 9 is a graph illustrating a relationship between capacitance and contact pressure;

FIGS. 10A to 10F are section views illustrating a second manufacturing method of a sensor mat and a second construction example of the sensor mat;

FIGS. 11A to 11G are section views illustrating a third manufacturing method of a sensor mat and a third construction example of the sensor mat;

FIGS. 12A to 12F are section views illustrating a fourth manufacturing method of a sensor mat and a fourth construction example of the sensor mat;

FIGS. 13A to 13E are section views illustrating a fifth manufacturing method of a sensor mat and a fifth construction example of the sensor mat;

FIG. 14 is a section view illustrating a sixth construction example of the sensor mat;

FIG. 15 is a section view illustrating a seventh construction example of the sensor mat;

FIG. 16 is a section view illustrating an eighth construction example of the sensor mat;

FIG. 17 is a plan view illustrating an occupant detection sensor (contact pressure sensor section) in a state where an occupant is deeply seated on a seat;

FIG. 18 is a plan view illustrating an occupant detection sensor (contact pressure sensor section) in a state where the occupant is shallowly seated on a seat;

FIG. 19 is a plan view illustrating a first arrangement example of opposed electrodes;

FIG. 20 is a plan view illustrating a construction example of an occupant detection sensor (contact pressure sensor section); and

FIG. 21 is a plan view illustrating a second arrangement example of opposed electrodes.

### DETAILED DESCRIPTION

Embodiments will be described with reference to the drawings. Here, unless otherwise particularly described, a word of “connection” means an electric connection. Directions such as an up-down direction and a left-right direction are designated based on those in the drawings.

### First Embodiment

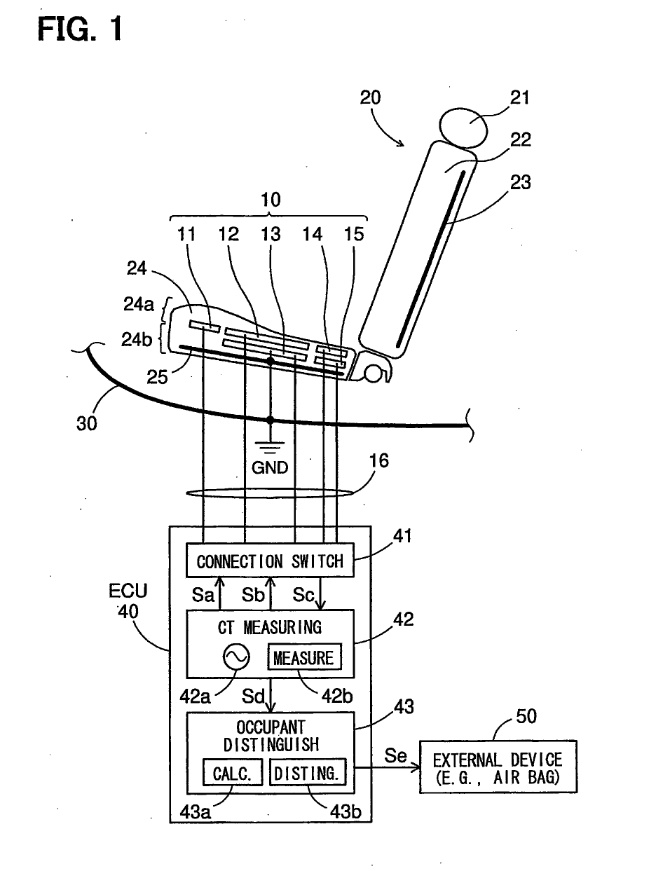

A first embodiment will be described with reference to FIG. 1 to FIG. 13E. In the first embodiment, an electrostatic sensor section and a contact pressure sensor section are integrated. Here, since a sensor mat having the electrostatic sensor section and the contact pressure sensor section can have various forms, a first construction example to a fifth construction example will be described as examples of the sensor mat.

### First Construction Example

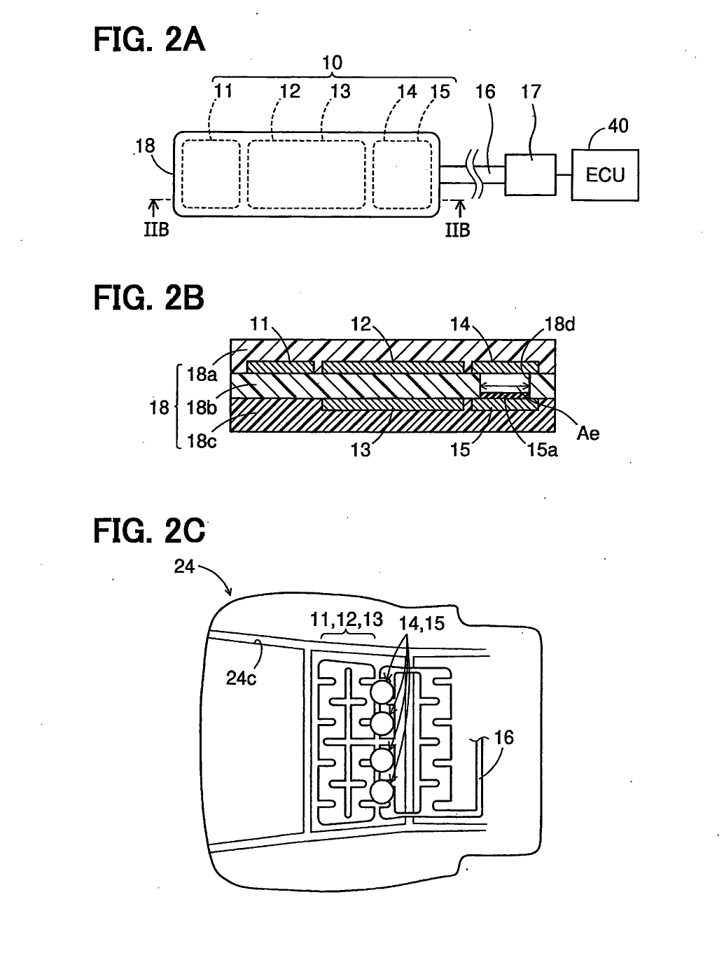

First, FIG. 1 shows a schematic view of a construction example of an occupant detection sensor. The occupant detection sensor shown in FIG. 1 includes an electrode part 10, an ECU 40, and the like. Electrodes of the electrode part 10 are connected to the ECU 40 by signal lines 16 and a connector 17 in such a way that signals can be transmitted between the electrodes and the ECU 40 (see FIG. 2A). The electrodes included in the electrode part 10 are constructed as, for example, a sensor mat 18 (see FIG. 2B). A portion or the entire portion of the occupant detection sensor is provided in a seat 20 (seating unit).

The seat 20 includes a headrest 21, cushion pads 22, 24, and seat frames 23, 25. A seat cover for covering the cushion pads 22, 24 is omitted in the drawing for simplification. The cushion pad 24 has the hip and the thigh of an occupant mainly received thereon. The cushion pad 22 constructs a “backrest” and has the back of the occupant received thereon. In this regard, each of the cushion pads 22, 24 and an urethane pad 19, which will be described later, correspond to a “pad member”.

The seat frames 23, 25 are electrically-conductive frames forming the framework of the seat 20. In this embodiment, the seat frames 23, 25 are used as ground and have the same electrical potential (which is denoted by “GND” in the drawing but whose potential is not always 0 V). These seat frames 23, 25 are connected to a guard electrode 13, a vehicle body 30, and a minus terminal of an electric power source (battery or fuel cell), thereby being set to the same potential as those. A body frame of a vehicle mainly corresponds to the vehicle body 30.

The electrode part 10 includes a sub electrode 11, a main electrode 12, a guard electrode 13, and opposed electrodes. The opposed electrodes are also referred to as “a cell” and includes a pair of electrodes of an upper electrode 14 and a lower electrode 15. Of these electrodes, the sub electrode 11, the main electrode 12, and the guard electrode 13 correspond to “the electrostatic sensor section”. The opposed electrodes correspond to “the contact pressure sensor section” and the upper electrode 14 corresponds to “one electrode” and the lower electrode 15 corresponds to “other electrode”. In this embodiment, the respective electrodes of the electrode part 10 are provided in the sensor mat 18 and are integrated with the sensor mat 18 (see FIG. 2B). Further, the lower electrode 15 has an insulating film 15a formed on one face (opposite face side) thereof (see FIG. 2B). The insulating film 15a can be made of any material as long as it is an insulating film.

The sensor mat 18 is provided in a seating face part 24a of the cushion pad 24. The seating face part 24a corresponds to an upper portion of the cushion pad 24, for example, a given region (for example, a region from the obverse face of a surface skin of the seat to the top of the cushion pad) including a seating face (obverse face) on which the occupant is seated. A lower portion of the cushion pad 24 excluding the seating face part 24a corresponds to a non-seating face part 24b. The sensor mat 18 may be typically arranged on the surface of the cushion pad 24. In this case, another pad member (for example, urethane pad) may be interposed between the sensor mat 18 and cushion pad 24. Alternatively, the sensor mat 18 may be arranged in the cushion pad 24 within the region of the seating face part 24a.

There is no restriction on the shape, thickness, and area of each electrode of the electrode part 10. As described above, the sensor mat 18 is arranged approximately parallel to the seating face of the cushion pad 24, so that the respective electrodes of the electrode part 10 are also arranged approximately parallel to the seating face of the cushion pad 24. A phrase of “arranged approximately parallel to the seating face” includes “arranged parallel to the seating face of the cushion pad 24” and “arranged non-parallel to the seating face while angle to the seating face is being within a given angle range”.

The main electrode 12 is arranged on the seating face part side of the sensor mat 18. The sub electrode 11 is arranged separately from the main electrode 12 in a plane direction. The guard electrode 13 is arranged opposed to the main electrode 12. The guard electrode 13 is between the main electrode 12 and the seat frame 25. The guard electrode 13 may or may not be opposed to the sub electrode 11. This guard electrode 13 prevents noises from entering the main electrode 12 from an opposite side of the seating face (lower side in the drawing). The positional relationship between the electrostatic sensor section (the sub electrode 11, the main electrode 12, and the guard electrode 13) and the contact pressure sensor section (the upper electrode 14 and the lower electrode 15) may be arbitrary. In this embodiment, a positional relationship between the upper electrode 14 and the lower electrode 15 is similar to a positional relationship between the main electrode 12 and the guard electrode 13. However, the upper electrode 14 and the lower electrode 15 may have arbitrary positional relationship with the sub electrode 11. That is, the upper electrode 14 and the lower electrode 15 may be arranged side by side with the sub electrode 11 or may be arranged separately from the sub electrode 11 in the plane direction (see FIG. 2B).

Further, also a planar positional relationship between the electrostatic sensor section (the sub electrode 11, the main electrode 12, and the guard electrode 13) and the contact pressure sensor section (the upper electrode 14 and the lower electrode 15) may be arbitrary. For example, in arrangement on a plane shown in FIG. 2C, the electrostatic sensor section (the sub electrode 11, the main electrode 12, and the guard electrode 13) is arranged on a front portion (left portion in the drawing) and on a rear portion (right portion in the drawing) of the cushion pad 24. The contact pressure sensor section (the upper electrode 14 and the lower electrode 15) is arranged in the center portion of the cushion pad 24. Although not shown in the drawing, these sensor sections may be arranged in a way opposed to the above example . . . . That is, the contact pressure sensor section may be arranged on the front portion and on the rear portion of the cushion pad 24, and the electrostatic sensor section may be arranged in the center portion of the cushion pad 24. These sensor sections may be arranged in different ways according to kind of vehicle having the seat 20.

A magnitude relation between areas of the respective electrodes of the electrode part 10 may be arbitrary. The areas of the respective electrodes may be set in such a way that the area of the sub electrode is smaller than the area of the main electrode. Alternatively, the area of the sub electrode may be equal to the area of the main electrode. Alternatively, the area of the sub electrode may be larger than the area of the main electrode. The same is applicable to the opposed electrodes (upper electrode 14 and the lower electrode 15). As the area of the electrode is larger (wider), capacitance (which is a capacity of storing electric charge) increases and sensitivity improves.

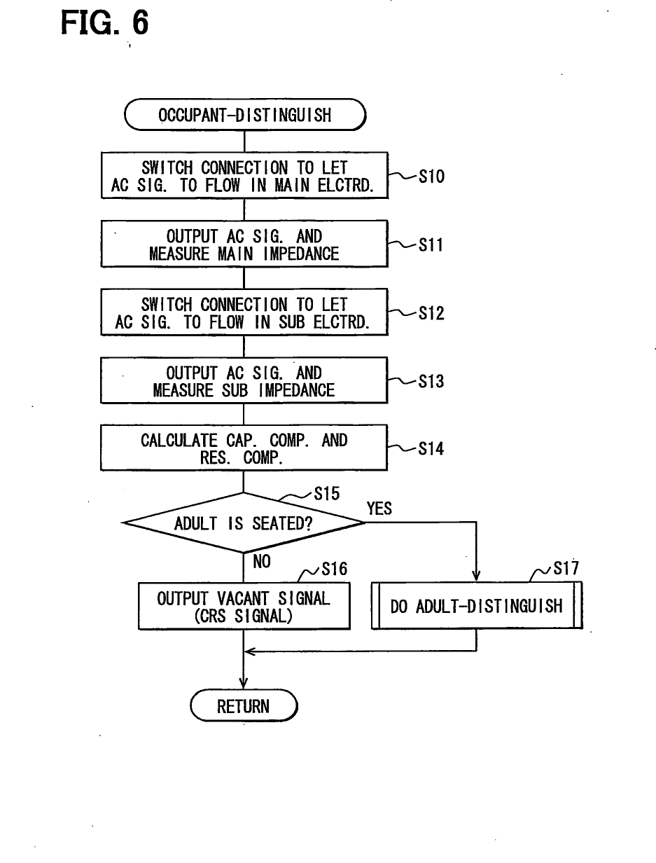

The ECU 40, which is an example of a processing unit, includes a connection switching section 41, a capacitance measuring section 42, and an occupant distinguishing section 43. The connection switching section 41 has a function of switching a connection on the basis of a switching signal Sa transmitted from the capacitance measuring section 42. The connection switching section 41 includes a contact switch, an electromagnetic switch (including a relay), a semiconductor switch (including a semiconductor relay), or the like. The switching signal Sa is transmitted at the time of measuring one or both of a main impedance and a sub impedance. The terms of the main impedance and the sub impedance are used to distinguish impedances between two points (including impedance between electrodes, impedance between terminals, etc.). A switching operation of the connection switching section 41 will be described later with reference to FIG. 6.

The capacitance measuring section 42 has a function of outputting an alternate current signal Sb and of measuring impedance on the basis of the value of current flowing through the electrode part 10. An imaginary part of the impedance is a capacitance component corresponding to “the capacitance”. A real part of the impedance is a resistance component. This capacitance measuring section 42 includes a signal source 42a and a measuring portion (means) 42b. The signal source 42a has a function of generating the alternate current signal Sb. As long as the alternate current signal Sb allows impedance measurement, there is no restriction on the waveform, amplitude, and frequency of the alternate current signal.

The measuring portion 42b has a function of supplying the alternate current signal Sb to two points, which are connected by the connection switching section 41, to measure impedance between them. An impedance measured when the alternate current signal Sb is supplied to at least the main electrode 12 is referred to herein as a main impedance. An impedance measured when the alternate current signal Sb is supplied to at least the sub electrode 11 is referred to herein as a sub impedance. An inter-electrode impedance (Zms) measured when the alternate current signal Sb is supplied to the main electrode 12 and the sub electrode 11 is defined as one kind of the sub impedance. The measuring portion 42b can further supply the alternate current signal Sb to between the upper electrode 14 and the lower electrode 15 serving as the opposed electrodes, thereby measuring an inter-electrode impedance (Zaf).

The occupant distinguishing section 43 has a function of distinguishing a seated state of occupant on the seat 20. Specifically, the occupant distinguishing section 43 can distinguish vacant seat, adult of small build, adult of large build, CRS (Child Restraint System on the seat etc., and outputs a distinguishing result signal Se (for example, a seating signal or a vacant signal) to an external unit 50 on an as-needed basis. The occupant distinguishing section 43 includes a calculating portion (means) 43a and a distinguishing portion (means) 43b. The calculating portion 43a calculates a capacitance component (corresponding to an imaginary value) and a resistance component (corresponding to a real value) of each impedance indicated by the measuring signal Sb transmitted from the capacitance measuring section 42. The distinguishing portion 43b distinguishes the occupant on the basis of the capacitance component of the main impedance, the resistance component of the sub impedance, and the capacitance component of the opposed electrodes. The external unit 50 may be an air bag unit for expanding an air bag in an emergency (in particular, an air bag ECU), other ECUs, or a processing unit.

FIGS. 2A to 2C are schematic views of a construction example of the electrode part 10. FIG. 2A is a plan view. FIG. 2B is a schematic section view of a portion of the sensor mat 18 taken along a line IIB-IIB in FIG. 2A. FIG. 2C is a plan view of the sensor mat 18 arranged on the cushion pad 24. Section views other than FIG. 2B are also ones taken along line corresponding to the line IIB-IIB shown in FIG. 2A.

As shown in FIG. 2A, the respective electrodes (that is, the sub electrode 11, the main electrode 12, the guard electrode 13, the upper electrode 14, and the lower electrode 15) of the electrode part 10 are in the sensor mat 18. In other words, these electrodes are integrated with the sensor mat 18.

The sensor mat 18 shown in FIG. 2B includes a first covering member 18a, a planar member 18b, and a second covering member 18c. In FIG. 2B, the sub electrode 11, the main electrode 12, and the upper electrode 14 are in the first covering member 18a. The guard electrode 13 and the lower electrode 15 are in the second covering member 18c. The arrangement of the sub electrode 11, the main electrode 12, and the guard electrode 13 and the arrangement of the upper electrode 14 and the lower electrode 15 are the same as those in FIG. 1. The first covering member 18a and the second covering member 18c can be made of an arbitrary material, as long as the material allows the first covering member 18a to cover those electrodes to protect those electrodes. In this embodiment, a film (e.g., an insulating thin resin film) is used for the materials of first covering member 18a and the second covering member 18c. The planar member 18b is made of an insulating material (for example, an insulating film) and is arranged in common between the main electrode 12 and the guard electrode 13 and between the opposed electrodes (the upper electrode 14 and the lower electrode 15).

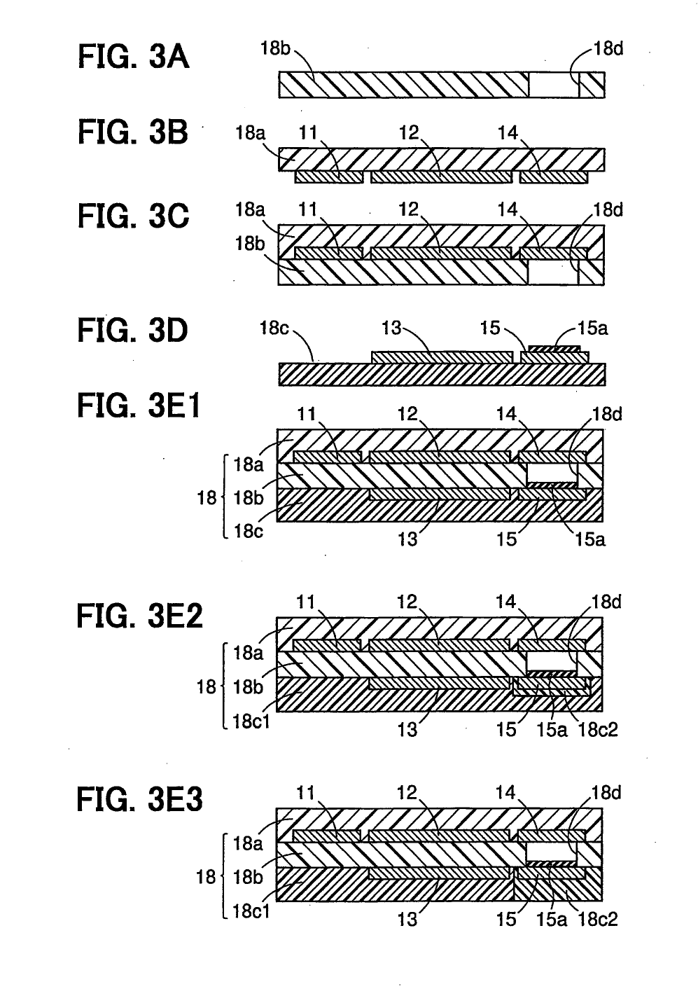

A first manufacturing method of the sensor mat 18 will be described with reference to FIGS. 3A to 3E3. FIG. 3A shows a hole making process. FIG. 3B shows a first electrode forming process. FIG. 3C shows a first covering process. FIG. 3D shows a second electrode forming process. FIGS. 3E1, 3E2, 3E3 show a second covering process. In the present embodiment, an order in which these processes are performed is arbitrary and some processes may be performed at the same, except that (i) the hole making process should be performed first, (ii) the first covering process should be performed after the first electrode forming process, and (iii) the second covering process should be performed after the second electrode forming process. Further, an insulating film 15a is previously formed on one face (opposing side) of the lower electrode 15 in insulating film forming process. In this embodiment, these processes will be explained from FIG. 3A to FIG. 3E.

In the hole making process shown in FIG. 3A, a through hole 18d is made in the planar member 18b. In this process, the planar member 18b not having a hole may be prepared and then the through hole 18d may be made. Alternatively, the through hole 18d may be formed at the same time when the planar member 18b is formed. The through hole 18d is at a portion between the upper electrode 14 and the lower electrode 15, and hence becomes a space (air gap) for storing electric charges.

In the first electrode forming process shown in FIG. 3B, the sub electrode 11, the main electrode 12, and the upper electrode 14 are formed on the other face side of the first covering member 18a. Additionally, although not shown in the drawing, the electrodes other than the upper electrode 14 may be formed on one face side of the planar member 18b. In the above, the other face side refers to an opposite side from the seating face, and is described as a lower side in the drawing; the same applies hereinafter. Further, the one face side refers to a seating face side and is described as an upper side in the drawing; the same applies hereinafter).

In the first covering process shown in FIG. 3C, the other face side of the first covering member 18a, on which the sub electrode 11, the main electrode 12 and the upper electrode 14 are formed, is integrated with (for example, bonded to or welded to) the one face side of the planar member 18b having the through hole 18d. As a result, these electrodes are covered as shown in FIG. 3C.

In the second electrode forming process shown in FIG. 3D, the guard electrode 13 and the lower electrode 15 are formed on one face side of the second covering member 18c. Of these electrodes, the lower electrode 15 is formed so as to close the through hole 18d. Although not shown in the drawing, the guard electrode 13 may be formed on the other face side of the planar member 18b. Further, the second electrode forming process may be performed at the same time as (in parallel to) or before or after the first electrode forming process.

In the second covering process shown in FIGS. 3E1, 3E2, and 3E3, the one face side of the second covering member 18c, on which the guard electrode 13 and the lower electrode 15 are formed, is integrated with the other face side of the planar member 18b. As a result, these electrodes 13, 15 are covered. The second covering process may be performed at the same time as or before or after the first electrode forming process. FIG. 3E1 shows one example in which the guard electrode 13 and the lower electrode 15 are covered with the second covering member 18c made from a single material (for example, a single film). It should be noted that the construction example of the sensor mat 18 in FIG. 3E1 is the same as that of the sensor mat 18 shown in FIG. 2B. FIG. 3E2 shows another example in which the lower electrode 15 is covered with a second material 18c2 (for example, a film) and the entire other face side of the planar member 18b is covered with a first material 18c1 (called a resist coat). FIG. 3E3 shows yet another example in which a portion including the guard electrode 13 is covered with the first material 18c1 and a portion including the lower electrode 15 is covered with the second material 18c2. The first material 18c1 and the second material 18c2 correspond to the second covering member 18c. In this way, the sensor mats 18 of the respective construction examples shown in FIGS. 3E1, 3E2, and 3E3 can be manufactured.

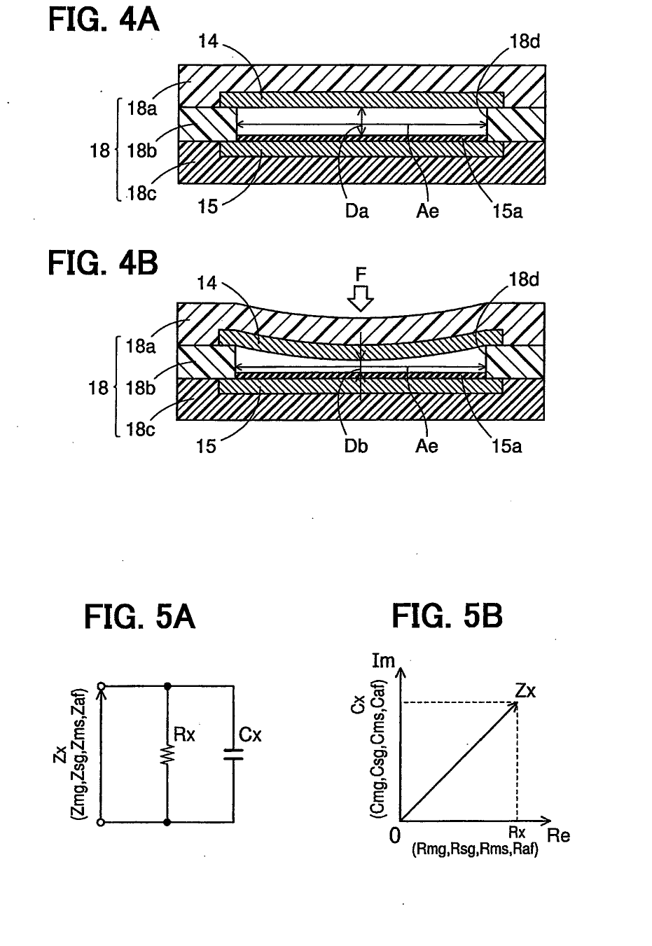

The capacitance generated between the opposed electrodes (the upper electrode 14 and the lower electrode 15) of the sensor mat 18 will be described with reference to FIGS. 4A and 4B. FIG. 4A shows a non-loaded state where the occupant is not seated and no load is applied to the sensor mat 18. FIG. 4B shows a loaded state where the occupant is seated and the load is applied to the sensor mat 18.

In the non-loaded state shown in FIG. 4A, the upper electrode 14 and the lower electrode 15 have a constant distance Da therebetween irrespective of locations. The distance Da is the same between the center portion and the vicinity of a side wall of the through hole 18d. In contrast to this, in the loaded state shown in FIG. 4B, a load F caused by the seated occupant is applied to the upper electrode 14 through the first covering member 18a, so that the upper electrode 14 and the lower electrode 15 have a shortest distance Db (Db<Da) at the center portion of the through hole 18d. The distance approaches the distance Da as the position comes closer to the side wall of the through hole 18d. As the load F becomes larger, the distance Db becomes smaller. As the distance between the upper electrode 14 and the lower electrode 15 becomes shorter, the capacitance becomes larger. Thus, when the capacitance (specifically, a later-described capacitance component Caf) is measured, the occupant applying the load F can be distinguished.

FIGS. 5A and 5B show a relationship between impedance and component. FIG. 5A shows an equivalent circuit and FIG. 5B shows a graph of a relationship between an imaginary part and a real part. As shown in FIG. 5A, impedance Zx measured by the connection switching section 41 is expressed by an equivalent circuit in which a capacitance component Cx and a resistance component Rx are connected in parallel to each other. As shown in FIG. 5B, the capacitance component Cx corresponds to an imaginary part Im and the resistance component Rx corresponds to a real part Re. The impedance Zx may be the main impedance Zmg or the sub impedance Zsg (inter-electrode impedance Zms). The capacitance component Cx may be the laer-described capacitance components Cmg, Csg, Cms or Caf. The resistance component Rx may be the later-described resistance components Rmg, Rsg, Rms, or Raf. In the following, a suffix “mg” is attached to an element relating to the main impedance Zmg. Similarly, a suffix “sg” is attached to an element relating to the sub impedance Zsg. A suffix “ms” is attached to an element relating to the inter-electrode impedance Zms between the main electrode 12 and the sub electrode 11. Further, a suffix “af” is attached to an element relating to an inter-electrode impedance Zaf between the opposed electrodes.

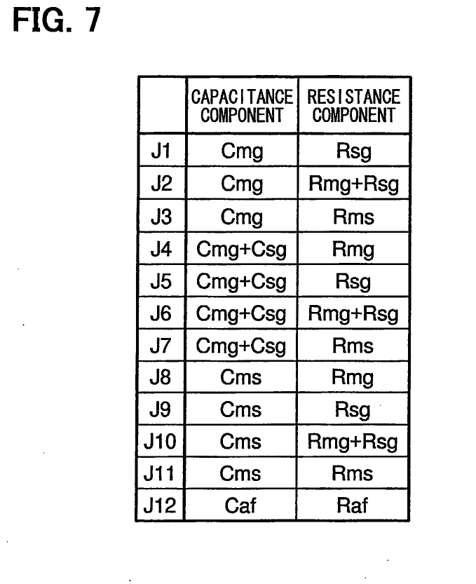

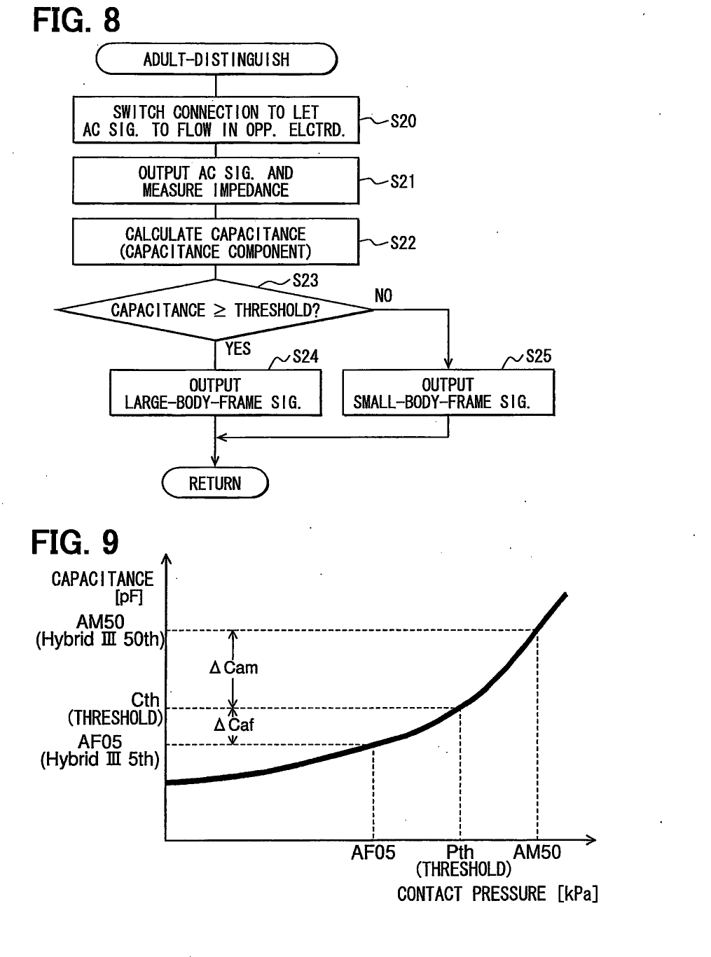

A process of distinguishing an occupant performed by the ECU 40 of the occupant detection sensor will be illustrated with reference to FIG. 6 to FIG. 9. FIG. 6 is a flowchart illustrating a procedure of an occupant distinguishing process. FIG. 7 is diagram illustrating a list of connection switching for acquiring a capacitance component and a resistance component. FIG. 8 is a flowchart illustrating a procedure of an adult distinguishing process. FIG. 9 is a graph illustrating a relationship between a first capacitance corresponding to the capacitance component Caf and a contact pressure corresponding to the load F. In FIG. 6 and FIG. 8, the ECU 40 performing steps S10, S12, and S20 can correspond to the connection switching section 41. The ECU 40 performing steps S11, S13, S14, S21, and S22 can correspond to the capacitance measuring section 42. The ECU performing steps S14 to S18 and steps S23 to S25 can correspond to the occupant distinguishing section 43.

When the ECU 40 is in operation, the ECU 40 repeatedly perform the occupant distinguishing process shown in FIG. 6. In step S10, the connection switching section 41 switches to a certain connection allow the alternate current signal Sb to flow through the main electrode 12. In step S11, the alternate current signal Sb is outputted and the main impedance Zmg is measured on the basis of the value of current flowing through the main electrode 12. Likewise, in step S12, the connection switching section 41 switches in another connection to allow the alternate current signal Sb to flow through the sub electrode 11. In step S13, the alternate current signal Sb is outputted and the sub impedance Zsg (including the inter-electrode impedance Zms) is measured on the basis of the value of current flowing through the sub electrode 11 An order of S10, S11 and steps S12, S13 may be arbitrary. In step S14, the capacitance component Cx and the resistance component Rx are calculated on the basis of the main impedance Zmg measured in step S11 and the sub impedance Zsg (or the inter-electrode impedance Zms) measured in step S13 (step S14).

How the connection switching section 41 switches in steps S10, S12 depends on the capacitance component Cx and the resistance component Rx that are required in step S14. Examples of how the connection switching section 41 switches will be described with reference to FIG. 7. FIG. 7 illustrates switching operations J1 to J12 according to the capacitance component Cx and the resistance component Rx. In the following description, the switching operation J3, J5, and J11 will be specifically described as typical examples.

The switching operation J3 is as follows. In order to acquire the capacitance component Cmg and the resistance component Rsg and to measure the impedance Zx, the connection switching section 41 switches to a first connection which connects the main electrode 12 and the guard electrode 13, and additionally, the connection switching section 41 switches to a second connection which connects the sub electrode 11 and the guard electrode 13 Specifically, the connection switching section 41 switches to the first connection to connect the main electrode 12 and the guard electrode 13; thereby enabling measurement of the main impedance Zmg and calculation of the capacitance component Cmg based on the main impedance Zmg. This capacitance component Cmg corresponds to “the second capacitance”. Further, the connection switching section 41 switches to the second connection to connect the sub electrode 11 and the guard electrode 13, thereby enabling measurement of the inter-electrode impedance Zms and calculation of the resistance component Rms based on the inter-electrode impedance Zms.

The switching operation J5 is as follows. In order to acquire the capacitance component (Cmg+Csg) and the resistance component Rsg and to measure the impedance Zx as in the case of the switching operation J3, the connection switching section 41 switches to a first connection which connects the main electrode 12 and the guard electrode 13, and additionally, the connection switching section 41 switches to a second connection which connects the sub electrode 11 and the guard electrode 13. Specifically, the connection switching section 41 switches to the first connection to connect the main electrode 12 and the guard electrode 13, thereby enabling measurement of the main impedance Zmg and calculation of the capacitance component Cmg based on the main impedance Zmg. Further, the connection switching section 41 switches to the second connection to connect the sub electrode 11 and the guard electrode 13, thereby enabling measurement of the sub impedance Zsg and calculation of the capacitance component Csg and the resistance component Rsg based on the sub impedance Zsg. These capacitance components Cmg and Csg are added together to obtain the capacitance component (Cmg+Csg).

The switching operation J11 is as follows. In order to acquire the capacitance component Cms and the resistance component Rms, the connection switching section 41 switches to a connection to connect the sub electrode 11 and the main electrode 12, thereby enabling measurement of the inter-electrode impedance Zms and calculation of the capacitance component Cms and the resistance component Rms based on the inter-electrode impedance Zms. This capacitance component Cms corresponds to a “third capacitance”. This switching operation J11 requires measurement of only the inter-electrode impedance Zms and does not require steps S10 and S11 to be performed.

Explanation returns to FIG. 6. In step S15, on the basis of the capacitance component Cx and the resistance component Rx calculated in step S14, it is distinguished with reference to a map for distinguishing an occupant whether or not an adult occupant is seated (step S15). In one embodiment, it is distinguished on the basis of the capacitance components Cmg, Csg, and Cms whether or not the adult occupant is seated. Alternatively, the seating state of an adult may be distinguished on the basis of the capacitance components Cmg, Csg, and Cms and the resistance components Rmg, Rsg, and Rms.

The map for distinguishing an occupant is recorded previously in a storage medium (for example, ROM, EEPROM, or flash memory) provided inside or outside the ECU 40. In the map for distinguishing an occupant, both of the capacitance component and the resistance component are prone to be larger as the temperature is higher. Further, both of the capacitance component and the resistance component are prone to be larger as the moisture is higher. A distinguishing manner using the map for distinguishing an occupant has been publicly known and hence the drawing and the description of the distinguishing method will be omitted.

If it is distinguished that an adult occupant is not seated (NO in step S15), a vacant signal (or a CRS signal) is outputted as a distinguishing result signal Se (step S16) and then the occupant distinguishing process is returned. If it is distinguished that an adult is seated (YES in step S15), the adult distinguishing process is performed (step S17) and then the occupant distinguishing process is returned.

The adult distinguishing process will be described with reference to FIG. 8. In the adult distinguishing process shown in FIG. 8, in step S20, the connection switching section 41 switches to the connection which allows the alternate current signal Sb to flow between the upper electrode 14 and the lower electrode 15, In step S21, the alternate current signal Sb is outputted and an inter-electrode impedance Zaf is measured on the basis of the value of current flowing through between the upper electrode 14 and the lower electrode 15. This corresponds to the switching operation J12 in FIG. 7. Specifically, in order to acquire the capacitance component Caf and the resistance component Raf, the connection switching section switches to the connection for the alternate current signal Sb to flow between the upper electrode 14 and the lower electrode 15, thereby enabling measurement of the inter-electrode impedance Zaf. The capacitance component Caf corresponds to the “first capacitance”.

Explanation Returns to FIG. 8. In step S22, at least the capacitance component Caf is calculated on the basis of the inter-electrode impedance Zaf measured in step S21. In S23, a determination as to whether or not the capacitance (that is, the capacitance component Caf) calculated in this way is equal to or larger than a threshold Cth is made with reference to the map for distinguishing an adult. It should be noted that the map for distinguishing an adult is recorded previously in the storage medium (for example, ROM, EEPROM, or flash memory) inside or outside the ECU 40 (see FIG. 9). If the capacitance (that is, the capacitance component Caf) calculated in step S22 is equal to or larger than the threshold Cth (YES in step S23), a large-build signal indicative of an adult of large build is outputted as a distinguishing result signal Se (step S24) and then the adult distinguishing process is returned. If the capacitance is smaller than the threshold Cth (NO in step S23), a small-build signal indicative of an adult of small build is outputted as a distinguishing result signal Se (step S25) and then the adult distinguishing process is returned.

In the above, in step S23, a determination as to whether an adult is an adult of large build or an adult of small build may be made on the basis of the capacitance component Caf and the resistance component Raf. In this case, not only the capacitance component Caf but also the resistance component Raf needs to be calculated in step S22. By taking into account the resistance component Raf, a distinguishing accuracy can be improved depending on the causes of a disturbance.

FIG. 9 illustrates the map for distinguishing an adult. In FIG. 9, a vertical axis designates capacitance and a horizontal axis designates contact pressure, and a relationship between the capacitance and the contact pressure is shown by a thick line. In the drawing, “AF05 (including Hybrid III 5th)” is an example of an adult of small build and corresponds to a body weight of an American female adult positioned at 5% of a population from the lightest weight side in the normal distribution of the body weights of American female adults. Further, “AM50 (including Hybrid III 50th)” is an example of an adult of large build and corresponds to a body weight of an American male adult positioned at 50% of the population (that is, an average body weight) in the normal distribution of the body weights of American male adults. The threshold Cth is set between the “AF05” and the “AM50”. A difference ΔCaf between the threshold Cth and the “AF05” and a difference ΔCam between the threshold Cth and the “AM50” become larger as the number of opposed electrodes becomes larger or the areas of the upper electrode 14 and the lower electrode 15 become larger. That is, it becomes possible to ensure a large tolerance at the time of performing the adult distinguishing process. In the above, a build other than the “AF05” and the “AF50” (for example, “JF05” or “JM50”) may be employed.

In the sensor mat 18 of the first construction example, as shown in FIG. 2B and FIGS. 3E1, 3E2, and 3E3, the insulating film 15a is on the one face (opposite face side) of the lower electrode 15 and the planar member 18b is integrated with a base. By contrast, in the below-described sensor mat 18 of second to fifth construction examples, an insulating film is absent on the lower electrode 15 as in the case of the upper electrode 14 and the planar member 18b is integrated with a base. The structure other than the sensor mat 18 in the second to fifth construction examples can be the same as in the first construction example.

### Second Construction Example

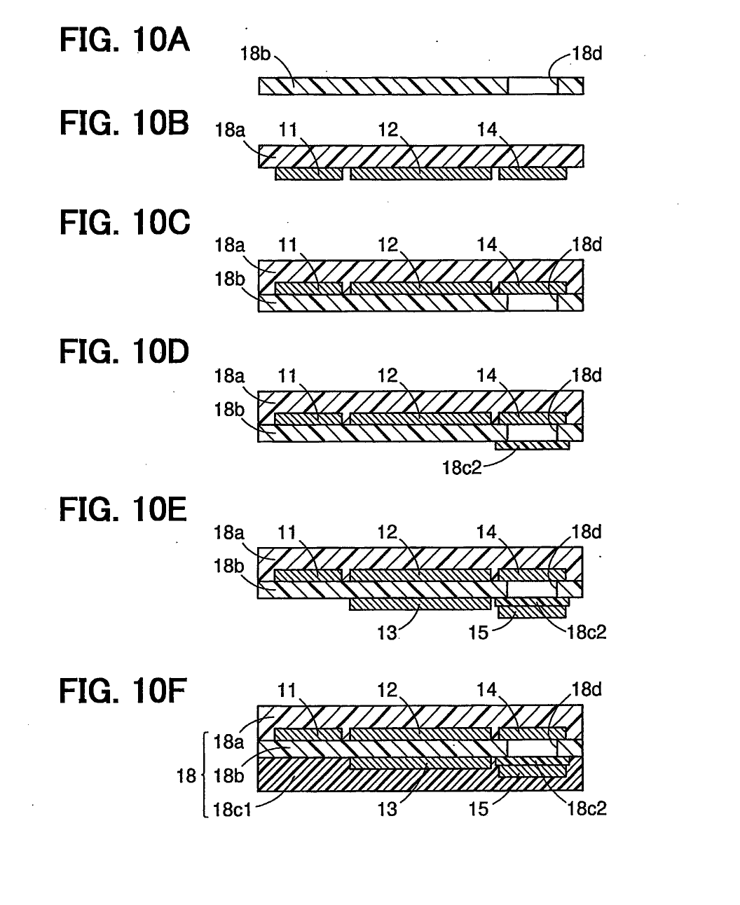

A second construction example will be described with reference to FIGS. 10A to 10F. FIG. 10A illustrates a hole making process, FIG. 10B illustrates a first electrode forming process, FIG. 10C illustrates a first covering process, FIG. 10D and FIG. 10F illustrate a second covering process, and FIG. 10E illustrates a second electrode forming process. An order in which these processes are performed may be arbitrary, except that the hole making process is performed first and the first covering process is performed after the first electrode forming process Further, the processes from the hole making process shown in FIG. 10A to the first covering process shown in FIG. 10C can be the same as the processes from FIG. 3A to FIG. 3C.

In the second covering process shown in FIG. 10D, a second material 18c2 is formed in the vicinity of the through hole 18d. In the second electrode forming process shown in FIG. 10E, the guard electrode 13 is formed on the planar member 18b and the lower electrode 15 is formed on the second material 18c2. In the second covering process shown in FIG. 10F, the entire other face side, which includes the guard electrode 13 and the lower electrode 15, of the planar member 18b is covered with a first material 18c1. In this way, the sensor mat 18 of the construction example shown in FIG. 10F is manufactured.

### Third Construction Example

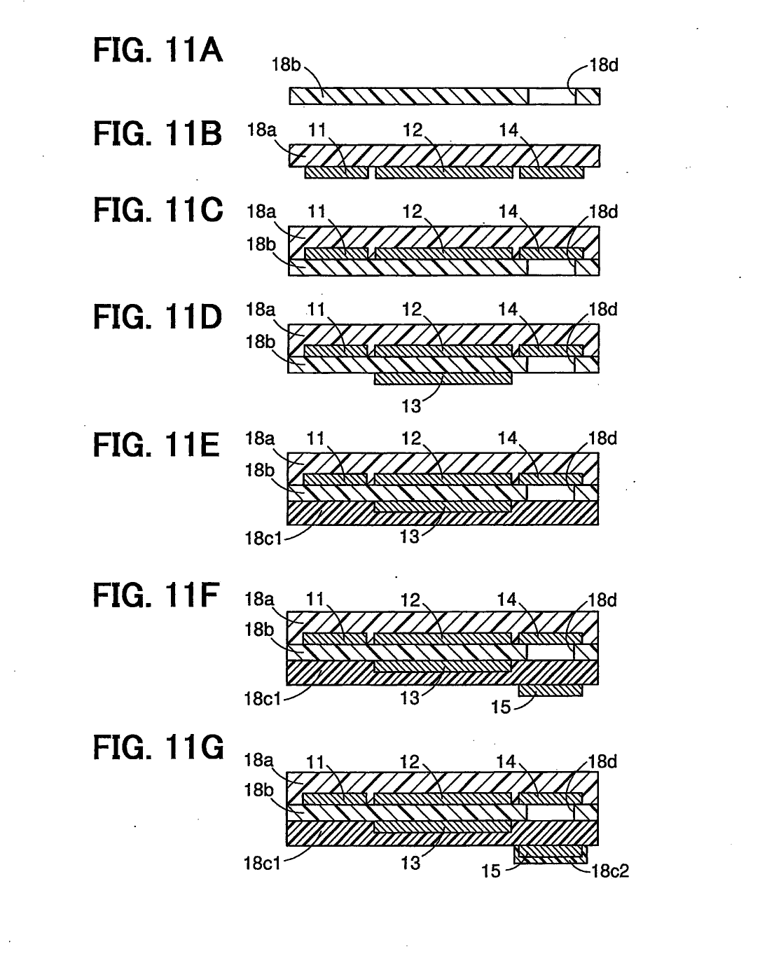

A third construction example will be described with reference to FIGS. 11A to 11G. FIG. 11A illustrates a hole making process, FIG. 11B illustrates a first electrode forming process, FIG. 11C illustrates a first covering process, FIG. 11D and FIG. 11F illustrate a second electrode forming process, and FIG. 11E and FIG. 11G illustrate a second covering process. An order in which these processes are preformed may be arbitrary, except that the hole making process is performed first and the first covering process is performed after the first electrode forming process. Further, the processes from the hole making process shown in FIG. 11A to the first covering process shown in FIG. 11C can be the same as the processes from FIG. 3A to FIG. 3C.

In the second electrode forming process shown in FIG. 11D, the guard electrode 13 is formed on a portion of the other face side of the planar member 18b so that the guard electrode 13 is not formed on the through hole 18d. In the second electrode forming process shown in FIG. 11E, the entire other face side, which includes the guard electrode 13, of the planar member 18b is covered with the first material 18c1. In the second covering process shown in FIG. 11F, the lower electrode 15 is formed on the other face side of the first material 18c1 so that the position of the lower electrode 15 corresponds to the positions of the upper electrode 14 and the through hole 18d. In the second covering process shown in FIG. 11G, the lower electrode 15 and its peripheral portion are covered with the second material 18c2. In this way, the sensor mat 18 of the construction example shown in FIG. 11G is manufactured.

### Fourth Construction Example

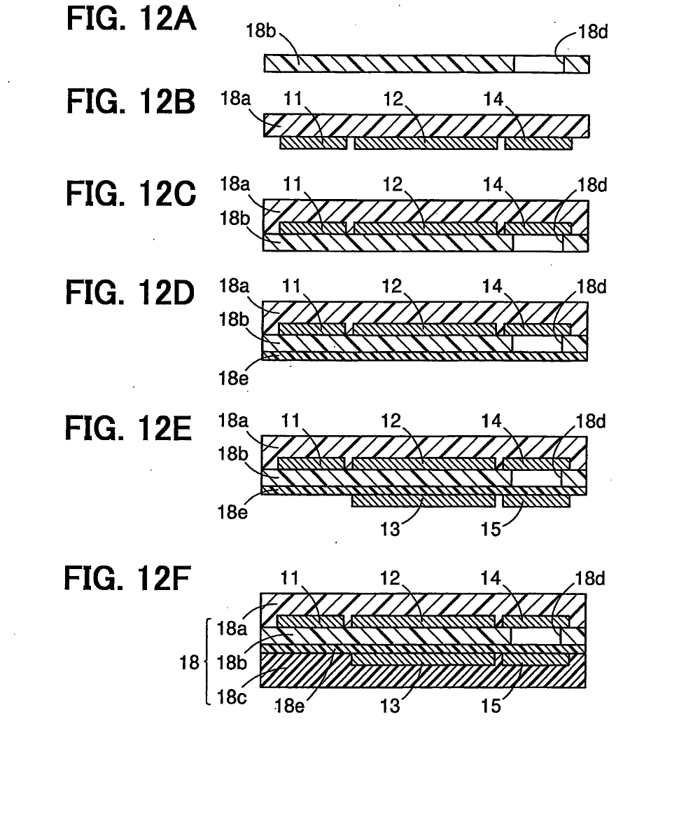

A fourth construction example will be described with reference to FIGS. 12A to 12F. FIG. 12A illustrates a hole making process, FIG. 12B illustrates a first electrode forming process, FIG. 12C illustrates a first covering process, FIG. 12D illustrates an insulating body forming process, FIG. 12E illustrates a second electrode forming process, and FIG. 12F illustrates a second covering process. Here, an order in which these processes are performed may be arbitrary except that the hole making process is performed first and the first covering process is performed after the first electrode forming process. Further, the processes from the hole making process shown in FIG. 12A to the first covering process shown in FIG. 12C can be the same as the processes from FIG. 3A to FIG. 3C.

In the insulating body forming process shown in FIG. 12D, an insulating body 18e is formed on the approximately entire other face side of the planar member 18b. In the second electrode forming process shown in FIG. 12E, the guard electrode 13 is formed on the other face side of the insulating body 18e so that position of the guard electrode 13 corresponds to position of the main electrode 12. Additionally, the lower electrode 15 is formed on the other face side of the insulating body 18e so that position of the lower electrode 15 corresponds to position of the upper electrode 14. In the second covering process shown in FIG. 12F, the other face side of the insulating body 18e is covered with the second covering member 18c. In this way, the sensor mat 18 of the construction example shown in FIG. 12F is manufactured.

### Fifth Construction Example

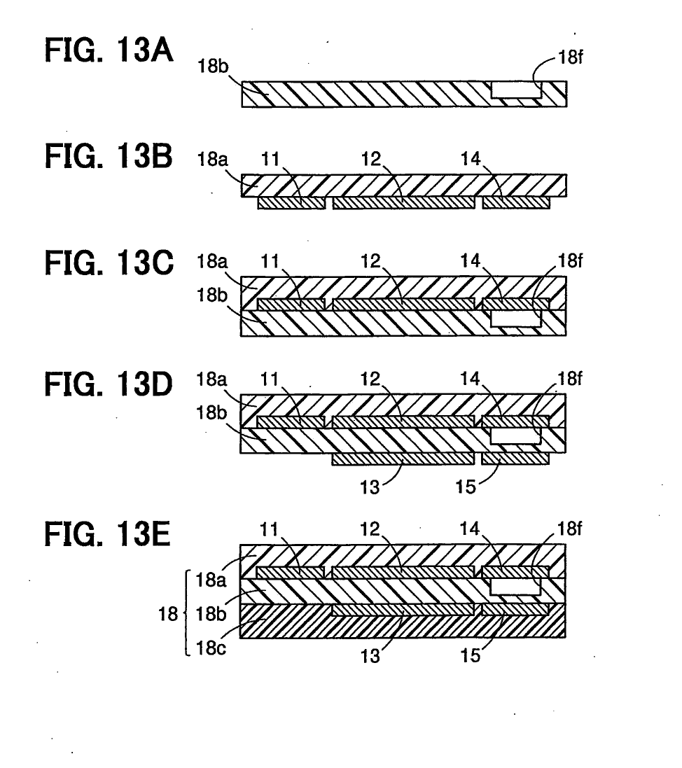

A fifth construction example will be described with reference to FIGS. 13A to 13E. FIG. 13A illustrates a hole making process, FIG. 13B illustrates a first electrode forming process, FIG. 13C illustrates a first covering process, FIG. 13D illustrates a second electrode forming process, and FIG. 13E illustrates a second covering process. An order in which these processes are performed is arbitrary, except that (i) the hole making process is performed first, (ii) the first covering process is performed after the first electrode forming process, and (iii) the second covering process is performed after the second electrode forming process.

In the fifth construction example, a depressed portion 18f is formed in the planar member 18b. in place of the through hole 18d, while the through hole 18d is formed in the planar member 18b in the first construction example. A bottom portion (thin portion) of the depressed portion 18f is formed to have a thickness to the extent that it is ensured that the bottom portion of the depressed portion 18f has the same insulating resistance as the above-described insulating film 15a. Since the fifth construction example is different only in the construction of the planar member 18b from the first construction example, the sensor mat 18 shown in FIG. 13E can be manufactured by basically the same manufacturing method as in the first construction example. However, the planar member 18b may be formed from an insulating material, so that the depressed portion 18f also shows an insulation performance. For this reason, the lower electrode 15 does not need to have the insulating film 15a thereon.

The seat 20 and the occupant detection sensor (more specifically, the electrode part 10 and the capacitance measuring section 42), which includes any one of the sensor mats 18 shown in the first construction example to the fifth construction example, are mounted in a transportation unit such as a vehicle or the like.

According to the first embodiment, an occupant detection sensor for detecting an occupant seated on a seat can be configured as follows. The occupant detection sensor comprises a contact pressure sensor section, an electrostatic sensor section, capacitance measuring section, and an occupant distinguishing section. The contact pressure sensor section includes one or more pairs of opposed electrodes (e.g., the upper electrode 14 and the lower electrode 15) arranged approximately parallel to a seating face part 24a of the seat 20. Each pair of opposed electrodes is opposed to each other with a predetermined interval therebetween. The electrostatic sensor section includes a main electrode 12 and a guard electrode 13. The main electrode 12 is arranged approximately parallel to the seating face part 24a of the seat 20. The guard electrode 13 is arranged between the main electrode 12 and a seat frame 25. The guard electrode has a same electric potential as the main electrode 12. The capacitance measuring section 42 measures the capacitance component Caf (also called a first capacitance) generated between the opposed electrodes and the capacitance component Cmg (also called second capacitance) generated between the main electrode 12 and the ground (which is the seat frames 23, 25 and the like in the present embodiment). The occupant distinguishing section 43 distinguishes the seating state of the occupant on the basis of the capacitance component Caf and the capacitance component Cmg (see FIG. 1, FIGS. 2A to 2C, FIG. 6, and FIG. 8). According to this configuration, the occupant distinguishing section 43 can highly-accurately distinguish the seating state of the occupant on the basis of the capacitance component Caf and the capacitance component Cmg.

The above occupant detection sensor can be configured as follows. A distance between the opposed electrodes decreases when load F of the occupant seated on the seat is applied (see FIG. 4). As the distance between the opposed electrodes decreases, the capacitance component Caf (the first capacitance) increases. For example, the distance Db shown in FIG. 4B is shorter than the distance Da shown in FIG. 4A, so that the capacitance component Caf becomes larger when the load F caused by the occupant being seated is applied. According to this configuration, the seating state of the occupant can be distinguished.

The above occupant detection sensor can be configured as follows. The electrostatic sensor section further includes the sub electrode 11 arranged separately from the main electrode 12 in a plane direction. The capacitance measuring section 42 measures the capacitance component Cms (the third capacitance) generated between the sub electrode 11 and the main electrode 12. The occupant distinguishing section 43 distinguishes the seating state of the occupant on the basis of the capacitance component Caf, the capacitance component Cmg, and the capacitance component Cms which are measured by the capacitance measuring section 42 (see FIG. 1, FIGS. 2A to 2C, and FIG. 6). According to this configuration, since the seating state of the occupant is distinguished on the basis of the capacitance component Caf, the capacitance component Cmg and the capacitance component Cms, it becomes possible to distinguish various modes (various states). Further, because of consideration of the capacitance component Cms, a false detection caused by a disturbance can be minimized.

The above occupant detection sensor can be configured as follows. The contact pressure sensor section and the electrostatic sensor section are integrated by use of an insulating planar member 18b that is arranged in common between the main electrode 12 and the guard electrode 13 and between the opposed electrodes (see FIGS. 3A to 3E3, FIGS. 10A to 10F, FIGS. 11A to 11G, FIGS. 12A to 12F, and FIGS. 13A to 13E). According to this configuration, since the contact pressure sensor section and the electrostatic sensor section are integrated by the use of the insulating planar member 18b, a manufacturing process can be simplified and a manufacturing cost can be reduced as compared with a case where individual planar members 18b are used for the respective sensor sections.

The above occupant detection sensor can be configured as follows. The contact pressure sensor section and the electrostatic sensor section are integrated by use of a first covering member 18a that covers both of the main electrode 12 and the upper electrode 14 (which is one of the opposed electrodes) (see FIGS. 3A to 3E3, FIGS. 10A to 10F, FIGS. 11A to 11G, FIGS. 12A to 12F, and FIGS. 13A to 13E). According to this configuration, since the first covering member 18a has a function of protecting the main electrode 12 and the upper electrode 14, it is possible to improve durability of the main electrode 12 and the upper electrode 14.

The above occupant detection sensor can be configured as follows. The contact pressure sensor section and the electrostatic sensor section are integrated by the use of the second covering member 18c (which may include a first material 18c1 and a second material 18c2) that covers both of the guard electrode 13 and the lower electrode 15 (which is the other of the opposed electrodes) (see FIGS. 3A to 3E3, FIGS. 10A to 10F, FIGS. 11A to 11G, FIGS. 12A to 12F, and FIGS. 13A to 13E). According to this configuration, since the second covering member 18c has a function of protecting the guard electrode 13 and the lower electrode 15, it is possible to improve the durability of the guard electrode 13 and the lower electrode 15.

The above occupant detection sensor can be configured as follows. The second covering member 18c is made of the first material 18c1 for covering the guard electrode 13 and of the second material 18c2 for covering the lower electrode 15 (see FIGS. 11A to 11G). According to this configuration, the second covering member 18c can reliably protect the guard electrode 13 and the lower electrode 15 and hence can improve the durability of the guard electrode 13 and the lower electrode 15.

The above occupant detection sensor can be configured as follows. The main electrode 12 and the guard electrode 13 of the electrostatic sensor section are formed on one face side of the planar member 18b and the other face side of the planar member 18b, respectively, so that position of the main electrode 12 corresponds to that of the guard electrode 13 (see FIGS. 3A to 3E3, FIGS. 10A to 10F, FIGS. 11A to 11G, FIGS. 12A to 12F, and FIGS. 13A to 13E). According to this configuration, the manufacturing process can be simplified and it is possible to reliably prevent noises from entering the main electrode 12 from the guard electrode 13 side.

The above occupant detection sensor can be configured as follows. The one (e.g., upper electrode 14) of the opposed electrodes and the other (lower electrode 15) of the opposed electrodes are formed on one face side of the planar member and the other face side of the planar member, respectively, so that position of the one of the opposed electrodes corresponds to that of the other of the opposed electrodes (see FIGS. 3A to 3E3, FIGS. 10A to 10F, FIGS. 11A to 11G, FIGS. 12A to 12F, and FIGS. 13A to 13E). According to this configuration, the manufacturing process can be simplified and the capacitance component Caf can be certainly generated between the electrodes.

The above occupant detection sensor can be configured as follows. At least one of the planar member 18b, the first covering member 18a and the second covering member 18c is made from an insulating film (see FIGS. 3A to 3E3, FIGS. 10A to 10F, FIGS. 11A to 11G, FIGS. 12A to 12F, and FIGS. 13A to 13E). According to this configuration, a total thickness of the contact pressure sensor section and the electrostatic sensor section can be reduced.

The above occupant detection sensor can be configured as follows. The planar member 18b defines a hole having a predetermined shape (e.g., the through hole 18d, the depressed portion 18f) at a portion between the opposed electrodes (see FIGS. 3A to 3E3, FIGS. 10A to 10F, FIGS. 11A to 11G, FIGS. 12A to 12F, and FIGS. 13A to 13E). According to this configuration, a space (air gap) for storing electric charges can be secured between the opposed electrodes. Thus, the capacitance component Caf can be certainly generated between the opposed electrodes.

The above occupant detection sensor can be configured as follows. The opposed electrodes, respectively, have facing surfaces, which face each other. An insulating film 15a is arranged on the facing surface of either one or both of the opposed electrodes. For example, the insulating film 15a is arranged on the facing surface of the lower electrode 15 (see FIGS. 3A to 3E3, FIGS. 10A to 10F, FIGS. 11A to 11G, FIGS. 12A to 12F, and FIGS. 13A to 13E). Alternatively, the insulating film 15a may be formed on the facing surface of the upper electrode 14 in stead of the lower electrode 15, or alternatively, the insulating film 15a may be formed on the facing surface of both of the upper electrode 14 and the lower electrode 15. In any of the above examples, a space for storing the electric charges can be formed and it is possible to prevent a trouble that both electrodes are brought into contact with each other to make the capacitance indefinite.

The above occupant detection sensor can be configured as follows. An insulating body is interposed between the hole of the planar member and the other of the opposed electrodes. The insulating body may be the second covering member 18c (specifically, the second material 18c2) or the lower electrode 15 (see FIGS. 10A to 10F, FIGS. 12A to 12F). According to this configuration, the through hole 18d acts as a space for storing the electric charges and the second covering member 18c and the insulating body 18e can prevent a trouble that both electrodes are brought into contact with each other to make the capacitance indefinite.

The above occupant detection sensor can be configured as follows. The capacitance measuring section 42 obtains capacitance on the basis of a value of current flowing between the electrodes (see FIGS. 5A and 5B). According to this configuration, since there is a specified relationship between the current and the capacitance, the capacitance (e.g., the capacitance component Caf, the capacitance component Cmg, and the capacitance component Cms) can be certainly obtained from the value of current.

The above occupant detection sensor can be configured as follows.

The occupant distinguishing section 43 distinguishes whether the occupant is an adult of small build or an adult of average build, by determining whether or not the first capacitance (e.g., capacitance component Caf) measured by the capacitance measuring section is greater than or equal to a threshold Cth (see FIG. 8 and FIG. 9). According to this configuration, by determining whether or not the capacitance component Caf generated between the opposed electrodes is equal to or larger than the threshold Cth, it is possible to distinguish whether the occupant is an adult of small build or an adult of average build.

According to the present embodiment, there is provided a method of manufacturing an occupant detection sensor. The method comprises: an insulating film forming step of forming the insulating film 15a, which is to be on one face (opposite face side) of the lower electrode 15; a hole making step of making a hole (the through hole 18d or the depressed portion 18f) at a predetermined position in the planar member 18b; a first electrode forming step of forming the upper electrode 14 and the main electrode 12, the main electrode 12 being to be approximately parallel to the seating face part 24a of the seat 20; a second electrode forming step of forming the guard electrode 13 and the lower electrode 15; a first covering step of covering the electrodes, which are formed in the first electrode forming step, with the first covering member 18a; and a second covering step of covering the electrodes, which are formed in the second electrode forming step, with the second covering member 18c (see FIGS. 3A to 3E3, FIGS. 10A to 10F, FIGS. 11A to 11G, FIGS. 12A to 12F, and FIGS. 13A to 13E). According to this method, since the respective electrodes can be protected by the first covering member 18a and the second covering member 18c, durability improves.

In the above first electrode forming step, the sub electrode 11 separated from the main electrode 12 in a plane direction may be further formed (see FIGS. 3A to 3E3, FIGS. 10A to 10F, FIGS. 11A to 11G, FIGS. 12A to 12F, and FIGS. 13A to 13E). According to this method, the capacitance component Cms can be generated between the sub electrode 11 and the main electrode 12. Various modes (various states) can be distinguished.

The above second covering step may comprise: a first material covering step of covering the guard electrode 13 with the first material 18c1; and a second material covering step of covering the lower electrode 15 with the second material 18c2 (see FIGS. 11A to 11G). According to this construction, the guard electrode 13 and the lower electrode 15 can be certainly protected and can be improved in durability.

### Second Embodiment

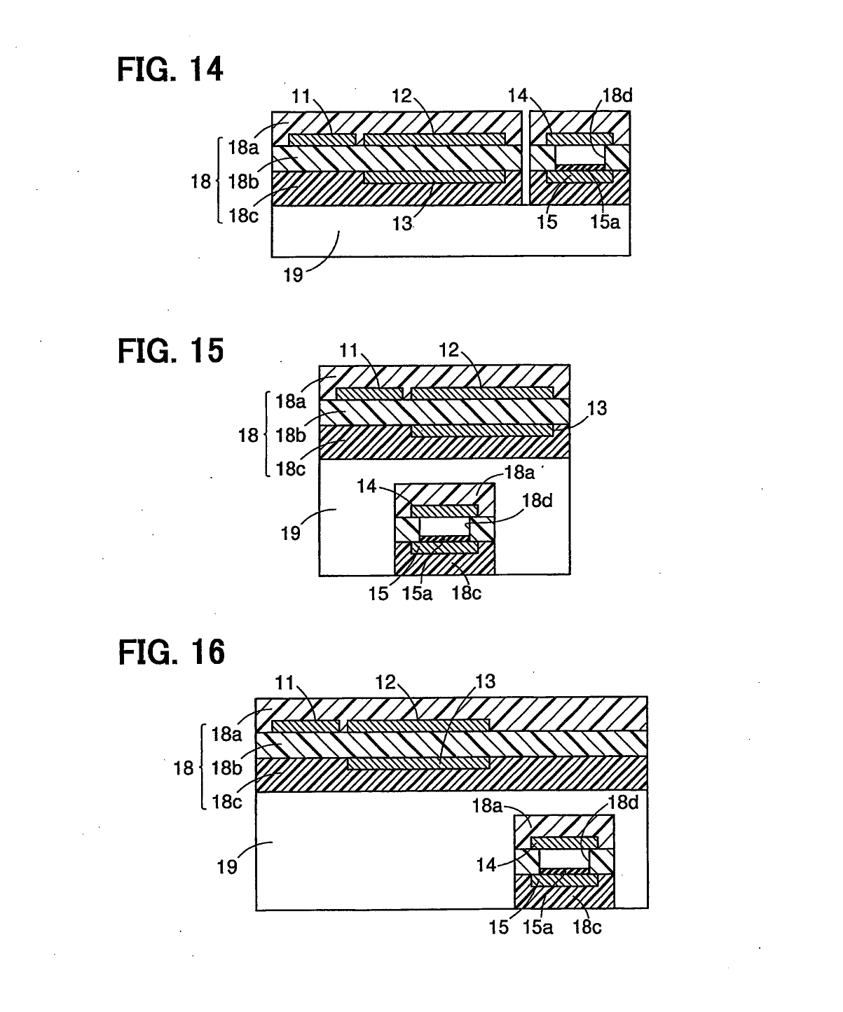

A second embodiment will be described with reference to FIG. 14 to FIG. 16.

In the second embodiment, the electrostatic sensor section and the contact pressure sensor section are separated from each other. In the second embodiment, structures other than the sensor mat 18 can be the same as those in the first embodiment. Like references are used to refer to like parts. Although not shown in the drawings, the cushion pad 24 is arranged under the urethane pad 19 shown in FIG. 14 to FIG. 16.

FIG. 14 illustrates a sixth construction example of the sensor mat 18. As shown in FIG. 14, the electrostatic sensor section and the contact pressure sensor section are integrally formed on the same face of a pad member. Each of the electrostatic sensor section (the sub electrode 11, the main electrode 12, and the guard electrode 13) and the contact pressure sensor section (the upper electrode 14 and the lower electrode 15) can be manufactured by the same manufacturing method as shown in FIGS. 3A to 3E3. Thereafter, the electrostatic sensor section and the contact pressure sensor section are fixed to one face side of the urethane pad 19. In this way, as shown in FIG. 14, the sensor mat 18 including the urethane pad 19 is manufactured.

FIG. 15 illustrates a seventh construction example of the sensor mat 18. As shown in FIG. 15, the electrostatic sensor section is fixed on one face of the urethane pad 19, and the contact pressure sensor section is fixed in the urethane pad 19, whereby the electrostatic sensor section and the contact pressure sensor section are integrated with the urethane pad 19. Each of the electrostatic sensor section (the sub electrode 11, the main electrode 12, and the guard electrode 13) and the contact pressure sensor section (the upper electrode 14 and the lower electrode 15) are manufactured by the same manufacturing method as the method shown in FIGS. 3A to 3E3. Thereafter, the electrostatic sensor section is fixed to the one face of the urethane pad 19 and the contact pressure sensor section is fixed in the urethane pad 19 (as shown in the drawing, in the depressed portion on the bottom face side). In this way, as shown in FIG. 15, the sensor mat 18 including the urethane pad 19 is manufactured.

FIG. 16 illustrates an eighth construction example of the sensor mat 18. As shown in FIG. 16, the electrostatic sensor section is fixed on one face of the urethane pad 19, and the contact pressure sensor section is fixed in the urethane pad 19, whereby the electrostatic sensor section and the contact pressure sensor section are integrated with the urethane pad 19. The construction example shown in FIG. 16 is different from the construction example shown in FIG. 15 in the following points. In the construction example shown in FIG. 15, the electrostatic sensor section and the contact pressure sensor section are arranged one above the other in a vertical direction (in a longitudinal direction in the drawing). In the construction example shown in FIG. 16, the electrostatic sensor section and the contact pressure sensor section are shifted from each other in a vertical direction. Specifically, the construction example shown in FIG. 16 is different from the construction example shown in FIG. 15 only in the positional relationship between the electrostatic sensor section and the contact pressure sensor section, so that the sensor mat 18 of the construction example shown in FIG. 16 can be manufactured by the same manufacturing method as in the construction example shown in FIG. 15. In this way, the sensor mat 18 including the urethane pad 19 can be manufactured as shown in FIG. 16.

Although not shown in the drawing, in place of the construction examples shown in FIG. 15 and FIG. 16, a construction may be employed in which the contact pressure sensor section is arranged between the urethane pad 19 and the cushion pad 24 and is integrated with them.

According to the second embodiment, the occupant detection sensor can be configured as follows. The contact pressure sensor section and the electrostatic sensor section are separated from each other and are provided with one urethane pad 19 (pad member) (see FIG. 14, FIG. 15, and FIG. 16). According to this configuration, the contact pressure sensor section and the electrostatic sensor section are constructed separately from each other but are arranged on a face or a depressed portion of the one urethane pad 19. That is, the contact pressure sensor section and the electrostatic sensor section can be integrated as a whole, so that the manufacturing process can be simplified and the manufacturing cost can be reduced as compared with a case where individual urethane pads 19 are used for the respective sensor sections.

The above occupant detection sensor can be configured as follows. The electrostatic sensor section and the contact pressure sensor section are on the same face of the urethane pad 19 (see FIG. 14). Alternatively, the electrostatic sensor section may be on one face of the urethane pad 19 and the contact pressure sensor section may be inside the urethane pad 19 (see FIG. 15 and FIG. 16). Alternatively, although not shown in the drawing, the electrostatic sensor section and the contact pressure sensor section may be separated and may be on opposite surfaces of the urethane pad 19. For example, the electrostatic sensor section may be on one face of the urethane pad 19 and the contact pressure sensor section may be on the other face of the urethane pad 19. Even if any of these structures is employed, the contact pressure sensor section, the electrostatic sensor section and the urethane pad 19 can be integrated. The manufacturing process can be simplified.

### Third Embodiment

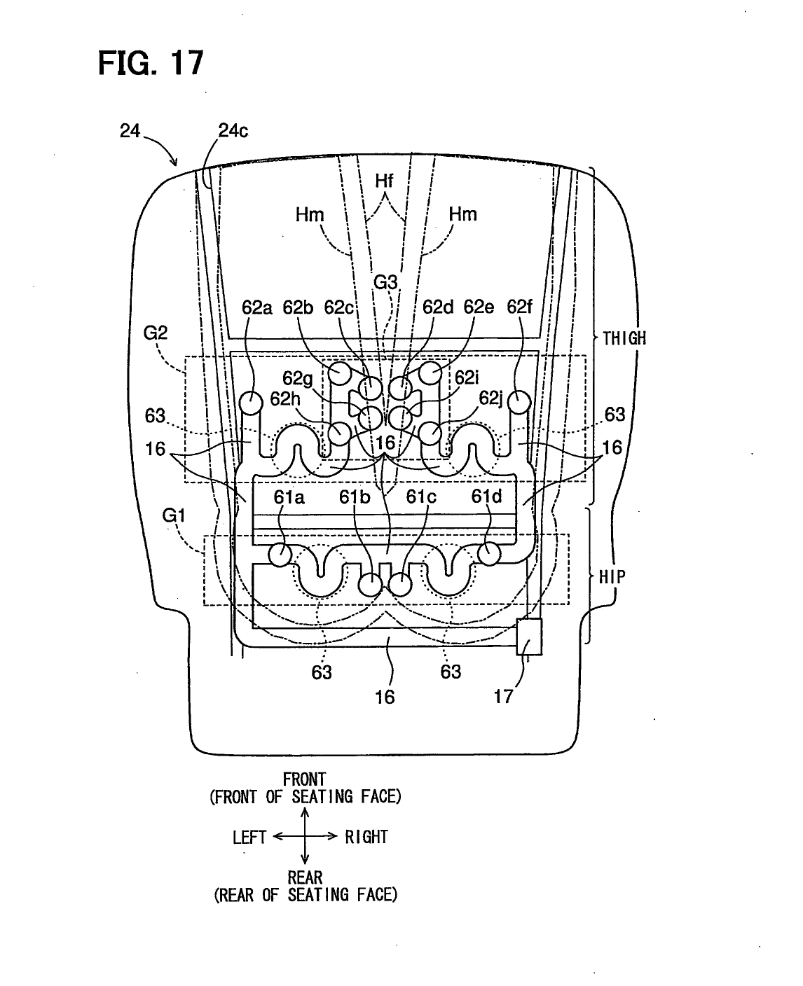

A third embodiment will be described with reference to FIG. 17 to FIG. 20. The third embodiment specifies a planar positional relationship (arrangement) of the contact pressure sensor section (the upper electrode 14 and the lower electrode 15). Like references are used to refer to like parts between the first and third embodiments. In the third embodiment, the electrostatic sensor section has the same construction as in the first and second embodiments.

The contact pressure sensor section of the occupant detection sensor shown in FIG. 17 to FIG. 20 comprises a first contact pressure sensor group G1 including a plurality of (in this embodiment, four) opposed electrodes 61a to 61d and a second contact pressure sensor group G2 including a plurality of (in this embodiment, ten) opposed electrodes 62a to 62j. The total number, the number of rows and the number of columns of opposed electrodes in the second contact pressure sensor group G2 may be arbitrary as long as one of the total number, the number of rows or the number of columns of opposed electrodes in the second contact pressure sensor group G2 is larger than that of opposed electrodes in the first contact pressure sensor group G1. In FIGS. 17, 18, 20, the first contact pressure sensor group G1 and the second contact pressure sensor group G2 are surrounded by a broken line, and are arranged in a front-rear direction (an up-down direction in the drawing) of the cushion pad 24. Specifically, the first contact pressure sensor group G1 is arranged on the rear portion of the seating face of the cushion pad 24 (in the down side in the drawing) and the second contact pressure sensor group G2 is arranged on the center portion of the seating face of the cushion pad 24.

The opposed electrodes 62b, 62c, 62d, 62e, 62g, 62h, 62i, and 62j is a third contact pressure sensor group G3. The third contact pressure sensor group G3 is a part of the second contact pressure sensor group G2 and is in the center region of the seating face part 24a. The third contact pressure sensor group G3 is arranged in such a way that a line segment connecting the opposed electrodes 62b, 62c, 62i, and 62j intersects with a line segment connecting the opposed electrodes 62d, 62e, 62g, and 62h.

A second electrode total area G2A, which is defined as the sum total of the areas of the opposed electrodes 62a to 62j in the second contact pressure sensor group G2, is larger than a first electrode total area G1A, which is defined as the sum total of the areas of the opposed electrodes 61a to 661dj in the first contact pressure sensor group G1 (that is, G2A>G1A). Here, the “area of the opposed electrodes” means an electrode area As shown in FIG. 2B and FIGS. 4A and 4B and corresponds to a cross-sectional area of the through hole 18d. The respective opposed electrodes relating to the opposed electrodes 61a to 61d and 62a to 62j have the same construction as those of the first and second embodiments and are connected to each other by a signal line 16.

Further, a third electrode area G3A, which is defined as the sum total of the areas of the opposed electrodes 62b, 62c, 62d, 62e, 62g, 62h, 62i, and 62j in the third contact pressure sensor group G3, is larger than a fourth electrode area G4A, which is defined as the sum total of the areas of the remaining opposed electrodes 61a, 61b, 61c, 61d, 62a, and 62f (that is, G3A>G4A).

Stretch portions 63 (portions surrounded by the dotted line in FIG. 17 to FIG. 20) are arranged between opposed electrodes 61b, 61c, 62b, 62c, 62d, 62e, 62g, 62h, 62i, and 62j on the center portion of the seating face and opposed electrodes 61a, 61d, 62a, and 62f on the left and right end of the seating face. In other words, the stretch portions 63 are arranged between two set of opposed electrodes separated from each other by a given distance or more. The stretch portion 63 is formed in U shape to bypass the signal line 16. Alternatively, the stretch portion 63 may be formed in other shapes (e.g., in the shape of a letter J, S, or W, or in a zigzag shape) as long as the stretch portion 63 is stretchable according to a variation in load F. The variation in load F may occur when the occupant is seated and leaves the seat. Additionally, the stretch portions 63 may be arranged in positions other than the portions shown in the drawing and the number of the stretch portions 63 may be arbitrary.

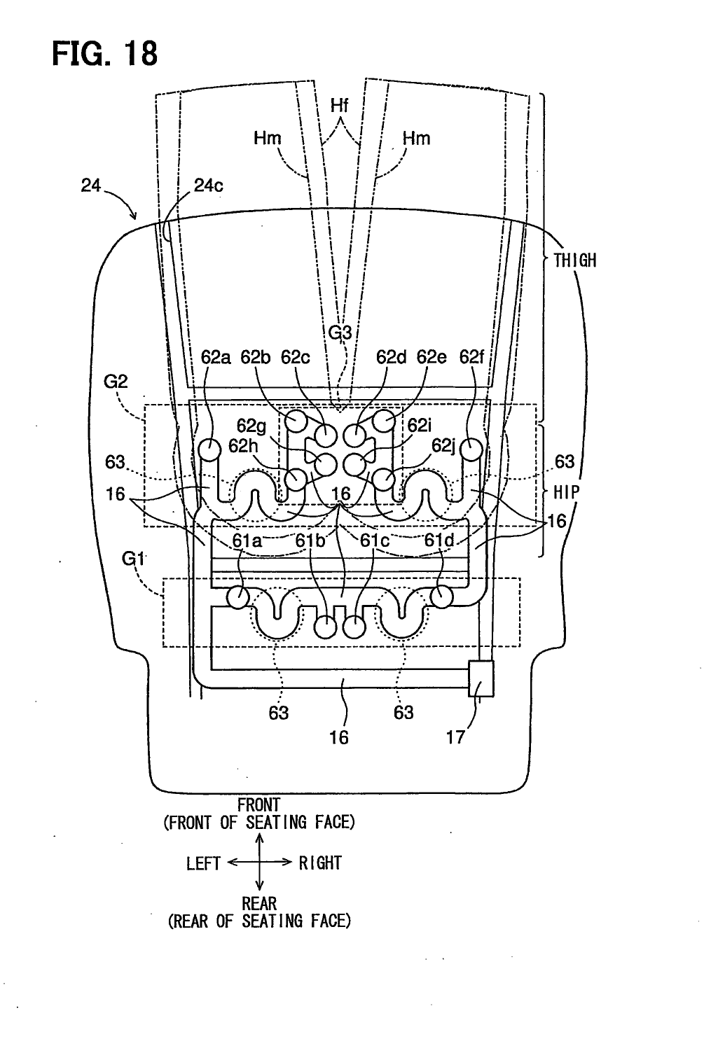

FIG. 17 illustrates a state where the occupant is deeply seated and FIG. 18 illustrates a state where the occupant is shallowly seated. In these drawings, an adult of large build Hm shown by the double dot and dash lines corresponds to “the above-described adult of large build”. An adult of small build Hf shown by the single dot and dash lines corresponds to “the above-described adult of small build”.

A difference between the adult of large build Hm and the adult of small build Hf in FIG. 17 is the capacitance detected by the opposed electrodes 62b, 62c, 62d, 62e, 62g, 62h, 62i, and 62j in the center portion of the seating face. Specifically, since the adult of large build Hm applies a small load F to the opposed electrodes 62c, 62d, 62g, and 62i, the small capacitance is detected. Since the adult of small build Hf applies a large load F to the opposed electrodes 62c, 62d, 62g, and 62i, the large capacitance is detected. Thus, the adult of large build Hm can be easily distinguished from the adult of small build Hf.

Comparison between the seating state in FIG. 17 and that in FIG. 18 facilitates understating of a determination as to whether the occupant is deeply seated or shallowly seated. Specifically, as shown in FIG. 17, when the occupant is deeply seated, the opposed electrodes 61a to 61d of the first contact pressure sensor group G1 receive a large load F. In contrast, when the occupant is shallowly seated as shown in FIG. 18, the opposed electrodes 61a to 61d of the first contact pressure sensor group G1 does not receive the load F (even if they receive the load F, the magnitude of the load F becomes very smaller than in FIG. 17). Thus, by calculating the capacitances of the opposed electrodes 61a to 61d using the calculating portion 43a, it is possible to easily distinguish the seating state of the occupant.

When the occupant is shallowly seated as shown in FIG. 18, it is possible to distinguish the adult of large build Hm from the adult of small build Hf by calculating the capacitances of the opposed electrodes 62a, 62f using the calculating portion 43a. Specifically, when the adult of large build Hm is seated, the opposed electrodes 62a, 62f receive the load F from portions near the pelvis of the hip, and as a result, the capacitances detected by the opposed electrodes 62a, 62f become large. In contrast, when the adult of small build Hf is seated, the opposed electrodes 62a, 62f receive the load F from end side portions of the hip, and as a result, the capacitances detected by the opposed electrodes 62a, 62f become small. Thus, even when the occupant is shallowly seated, the adult of large build Hm can be distinguished from the adult of small build Hf.

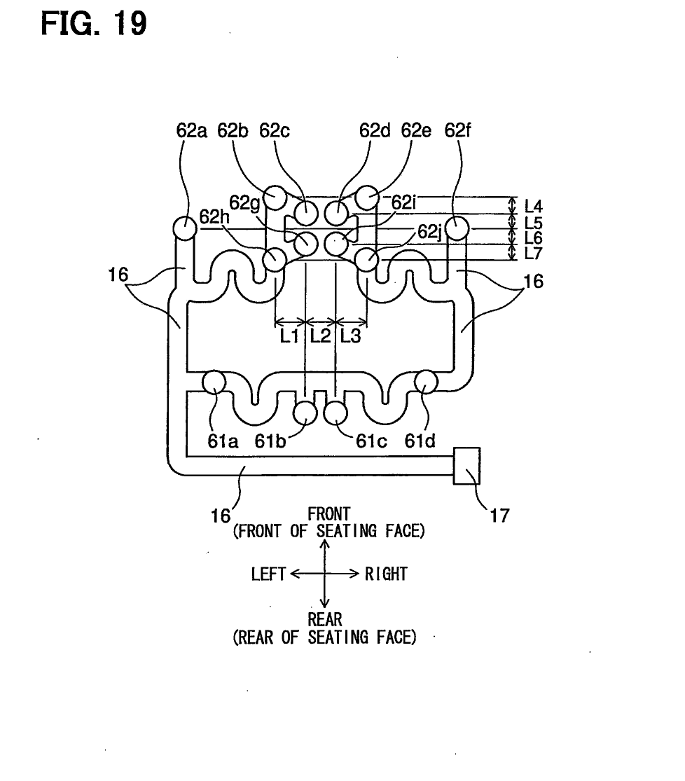

FIG. 19 shows an example of the arrangement of opposed electrodes in the first contact pressure sensor group G1 and the second contact pressure sensor group G2. For convenience of description, a longitudinal direction (up-down direction) in FIG. 19 is referred to as “a column direction” and a lateral direction (left-right direction) in FIG. 19 is referred to “a row direction”. Here, “an error within an acceptable range” includes an error in the design and an error in the manufacture. An equal interval and an indeterminate interval, which will be described below, can coexist. Both of the equal interval and the indeterminate interval correspond to “an approximately equal interval”.

The opposed electrodes 62b, 62h, the opposed electrodes 62c, 62g, 61b, the opposed electrodes 62d, 62i, 61c, and the opposed electrodes 62e, 62j form columns, respectively. The opposed electrodes 62b, 62h are separated from the opposed electrodes 62c, 62g by a column interval L1. The opposed electrodes 62c, 62g, 61b are separated from the opposed electrodes 62d, 62i, 61c by a column interval L2. The opposed electrodes 62d, 62i, 61c are separated from the opposed electrodes 62e, 62j by a column interval L3. The column intervals L1, L2, and L3 may be arbitrarily settable. For example, the column intervals L1, L2, and L3 may be set to an equal interval (L1=L2=L3) or may be set to indeterminate intervals containing an error within an acceptable range (L1˜L2˜L3).

The opposed electrodes 62b, 62e, the opposed electrodes 62c, 62d, the opposed electrodes 62a, 62f, the opposed electrodes 62g, 62i, and the opposed electrodes 62h, 62j form rows, respectively. The opposed electrodes 62b, 62e are separated from the opposed electrodes 62c, 62d by a row interval L4. The opposed electrodes 62c, 62d are separated from the opposed electrodes 62a, 62f by a row interval L5. The opposed electrodes 62a, 62f are separated from the opposed electrodes 62g, 62i by a row interval L6. The opposed electrodes 62g, 62i are separated from the opposed electrodes 62h, 62j by a row interval L7. The row intervals L4, L5, L6, and L7 may be arbitrarily settable. For example, the row intervals L4, L5, L6, and L7 may be set to an equal interval (L4=L5=L6=L7) or may be set to indeterminate intervals containing an error within an acceptable range (L4˜L5˜L6˜L7).

The opposed electrodes 62a, 62f, which are included in the second contact pressure sensor group G2 and arranged on the left and right end sides of the seating face, are arranged in such a way as to spread wider to the left and right sides of the seating face than the opposed electrodes 61a, 61d, which are included in the first contact pressure sensor group G1 and arranged on the left and right end sides of the seating face.

According to the third embodiment, the occupant detection sensor can be configured as follows. The contact pressure sensor section includes the first contact pressure sensor group G1 and the second contact pressure sensor group G2 arranged in a front-rear direction of the seat 20. The first contact pressure sensor group G1 is multiple pairs of opposed electrodes 61a to 61d. The second contact pressure sensor group G2 is multiple pairs of opposed electrodes 62a to 62J. The second electrode total area G2A, which is defined as the sum total of areas of the opposed electrodes 62a to 62j in the second contact pressure sensor group G2, is larger than the first electrode total area G1A, which is defined as the sum total of areas of the opposed electrodes 61a to 61d in the first contact pressure sensor group G1 (see FIG. 17 to FIG. 19). According to this configuration, even if the seating posture of the occupant is shifted in the front-rear direction of the seat 20 (see FIG. 17 and FIG. 18), the seating state of the occupant can be distinguished correctly.

The above occupant detection sensor can be configured as follows. The first contact pressure sensor group G1 is arranged on a rear portion of the seating face of the seat 20. The second contact pressure sensor group G2 is arranged on the center portion of the seating face of the seat 20 (see FIG. 17 to FIG. 19). According to this configuration, when the occupant is deeply seated, the seating state of the occupant can be detected with use of the first contact pressure sensor group G1 (see FIG. 17), whereas when the occupant is shallowly seated, the seating state of the occupant can be detected with use of the second contact pressure sensor group G2 (see FIG. 18). Thus, the seating state of the occupant can be detected correctly.

The above occupant detection sensor can be configured as follows. At least one of the number of rows, the number of columns and a total number of opposed electrodes 62a to 62j in the second contact pressure sensor group G2 is larger that that of opposed electrodes 61a to 61d in the first contact pressure sensor group G1 (see FIG. 17 to FIG. 19). According to this configuration, since the second contact pressure sensor group G2 is larger in the number of rows, the number of columns or the total number of the opposed electrodes than the first contact pressure sensor group G1, the seating state of the occupant can be distinguished correctly.

The above occupant detection sensor can be configured as follows. The opposed electrodes in one or both of the first contact pressure sensor group G1 and the second contact pressure sensor group G2 are arranged in three or more rows or in three or more columns at approximately equal intervals (see FIG. 17 to FIG. 19). According to this configuration, since the opposed electrodes are arranged at approximately equal intervals, the seating state of the occupant can be distinguished correctly on the basis of the capacitances of the respective opposed electrodes measured by the capacitance measuring section 42.

The above occupant detection sensor can be configured as follows. One of or both of the first contact pressure sensor group G1 and the second contact pressure sensor group G2 has a stretch portion 63. The stretch portion 63 is formed as a stretchable signal line 16 in a non-straight shape and connects the opposed electrodes (see FIG. 17 to FIG. 19). According to this configuration, the stretch portion 63 is elongated and contracted in response to the load F, which varies when the occupant is seated, leaves from the seat and is reseated. Thus, breaking of the signal line 16 is prevented.

The above occupant detection sensor can be configured as follows. The stretch portions 63 are arranged between a first set of opposed electrodes and a second set of opposed electrodes. The first set of opposed electrodes may be the opposed electrodes 61b, 61c, 62b, 62c, 62d, 62e, 62g, 62h, 62i, and 62j at the center portion of the seating face. The second set of opposed electrodes 61a, 61d, 62a, and 62f may be located closer to the left end or right ends of the seating face than the first set of opposed electrodes is (see FIG. 17 to FIG. 19). Although not shown in the drawing, the stretch portions 63 may be stretchable in the front-rear direction of the seating face (in the up-down direction in FIG. 17 to FIG. 19). According to these configurations, a breaking of the signal line 16 can be reliably presented.

The above occupant detection sensor can be configured as follows. A part of the opposed electrodes 62b, 62c, 62d, 62e, 62g, 62h, 62i, and 62j in the second contact pressure sensor group is arranged in a center region of the seating face part 24a of the seat 20 and is called th third contact pressure sensor group G3. The third electrode area G3A, which is defined as a sum total of areas of the part of the opposed electrodes in the second contact pressure sensor group, is larger than a fourth electrode area G4A. The fourth electrode area G4A is defined as a sum total of areas of the opposed electrodes 62a, 62 (the rest of opposed electrodes in the second contact pressure sensor group G2) and areas of the opposed electrodes 61a, 61b, 61c, 61d, 62a, and 62f in the first contact pressure sensor group G1 (see FIG. 17 to FIG. 19). According to this configuration, even if the occupant is deeply seated (see FIG. 17) and is shallowly seated (see FIG. 18), the part of the opposed electrodes in the second contact pressure sensor group G2 can distinguish the build and the seating state of the occupant correctly.

The above occupant detection sensor can be configured as follows. With respect to a left-to-right direction of the seating face part, a most-right pair 62f and a most-left pair 62a of the multiple pairs of the opposed electrodes in the second contact pressure sensor group are located outward than a most-right pair 61d and a most-left pair 61a of the multiple pairs of the opposed electrodes in the first contact pressure sensor group (see FIG. 17 to FIG. 19). According to this construction, the seating state of the occupant can be correctly distinguished irrespective of the seating position of the occupant.

The above occupant detection sensor can be configured as follows. The first contact pressure sensor group G1 detects a hip of the occupant and that the second contact pressure sensor group G2 detects a hip or a thigh of the occupant (see FIG. 17 to FIG. 19). According to this configuration, when the occupant is deeply seated, the first contact pressure sensor group G1 detects the hip of the occupant and the second contact pressure sensor group G2 detects the thigh of the occupant. When the occupant is shallowly seated, the second contact pressure sensor group G2 detects the hip of the occupant. Thus, irrespective of the seating position of the occupant, the seating state of the occupant can be distinguished correctly.

### Other Embodiments

Other embodiments will be described.

In the first and second embodiments, the resist coat is used as the first material 18c1 and the film is used as the second material 18c2 (see FIGS. 3A to 3E3, FIGS. 10A to 10F, FIGS. 11A to 11G, FIGS. 12A to 12F, and FIGS. 13A to 13E). Alternatively, the film may be used as the first material 18c1 and the resist coat may be used as the second material 18c2. Alternatively, an insulating material other than the resist coat and the film may be used as the first material 18c1 and the second material 18c2. Even if any one of the above is used for the first material 18c1 and the second material 18c2, the first material 18c1 and the second material 18c2 can secure the insulating performance and can provide the same advantages as in the first and second embodiments.

In the first and second embodiments, the sub electrode 11 is arranged separately from the main electrode 12 in a plane direction, as shown in FIG. 2B. That is, the sub electrode 11 and the main electrode 12 are arranged approximately on the same plane. Alternatively, the sub electrode 11 and the main electrode 12 may be arranged not on the same plane. For example, the sub electrode 11 may be closer to the seating face of the cushion pad 24 or the seat frame 25 than the main electrode 12 is. Since the capacitance component and the resistance component increase with increasing moisture between the electrode 11 and the seat frame acting as the ground, the electrode 11 closer to the seating face increase the capacitance component and the resistance component, whereas the electrode 11 closer to the seat frame 25 decreases the capacitance component and the resistance component. For example, these electrodes 11, 12 can be appropriately arranged at different positions according to the place (e.g., cold region and a warm hot region) the occupant detection sensor is used in. Thus, the occupant can be correctly distinguished according to place. Occupant distinguishing accuracy improves.

In the first and second embodiments, the air bag ECU is illustrated as the external unit 50 (see FIG. 1). Alternatively, in place of (or in addition to) the air bag ECU, the external unit 50 may include an ECU other than the air bag ECU (for example, engine ECU), a processing unit other than the ECU, or a computer (including a server and a personal computer) connected via a communication line. When the engine ECU acts as the external ECU 50, it is possible to prevent a vehicle from running in a state where the adult is not seated. When the other processing unit and the computer act as the external unit 50, it is possible to transmit the distinguishing result of the occupant with reliability.

In the first and second embodiments, the seat frames 23, 25 are illustrated as the ground (GND) having the same potential (see FIG. 1). Alternatively, in place of (or in addition to) the seat frames 23, 25, the ground (GND) may include a conductive member (for example, a metal wire, a metal net, or a conductive wire) in the seat 20 or a vehicle body 30. The ground (GND) other than the seat frames 23, 25 merely changes a reference potential for measuring the impedance, and thus, the same advantages are achievable.

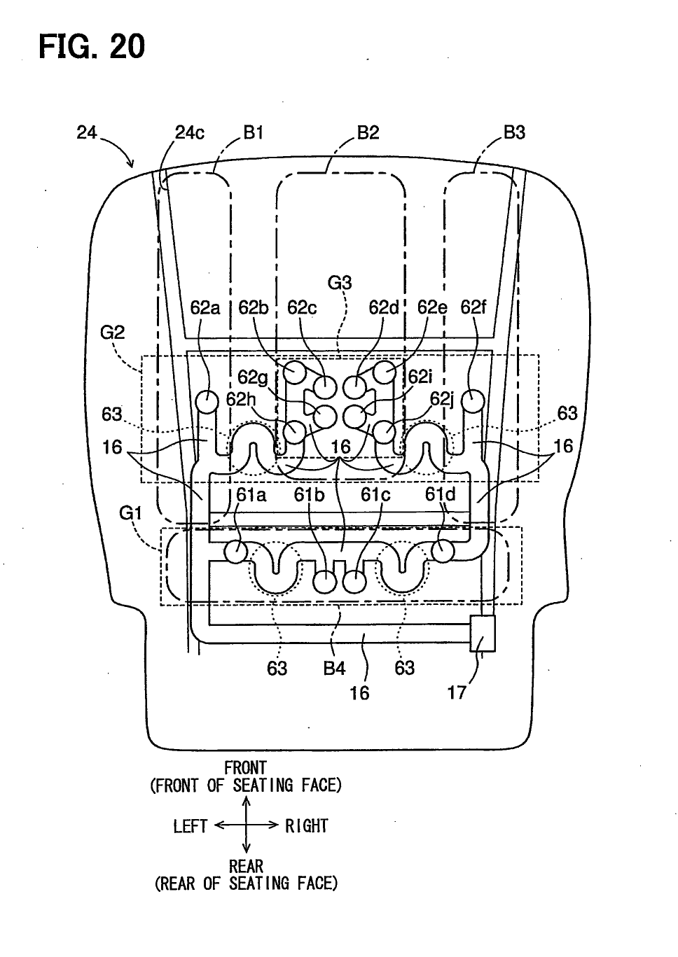

In the third embodiment, the first contact pressure sensor group G1 is arranged on the rear portion of the seating face of the cushion pad 24 and the second contact pressure sensor group G2 is arranged on the center portion of the seating face of the cushion pad 24 (see FIG. 17 to FIG. 19). Alternatively, the first contact pressure sensor group G1 and the second contact pressure sensor group G2 may be arranged in different ways. For example, as shown in FIG. 20, predetermined opposed electrodes may be arranged in respective arrangement regions B1, B2, B3, and B4. The arrangement region B1 corresponds to a left region of the seating face of the cushion pad 24 and receives the opposed electrodes 62a. The arrangement region B2 corresponds to a center region of the seating face of the cushion pad 24 and receives the opposed electrodes in the third contact pressure sensor group G3. The arrangement region B3 corresponds to a right region of the seating face of the cushion pad 24 and receives the opposed electrodes 62f. The arrangement region B4 corresponds to a rear region of the seating face of the cushion pad 24 and receives the opposed electrodes in the first contact pressure sensor group G1. According to this configuration, even when the seating posture of the occupant is shifted in the front-rear direction of the seat 20 (see FIG. 17 and FIG. 18), the seating state of the occupant can be distinguished correctly.

In the third embodiment, the opposed electrodes in the first contact pressure sensor group G1 and the second contact pressure sensor group G2 are formed to have the same shape (e.g., a circular shape) and the same area (see FIG. 17 to FIG. 19). Alternatively, the opposed electrodes may be formed to have different shapes (e.g., such a geometric shape as triangle and square, a combined shape made by combining two or more kinds of geometric shapes) and different areas. In this case, it may be preferable that the second electrode total area G2A be larger than the first electrode total area G1A and that the third electrode total area G3A be larger than the fourth electrode total area G4A. In this case also, the same advantages are achievable.

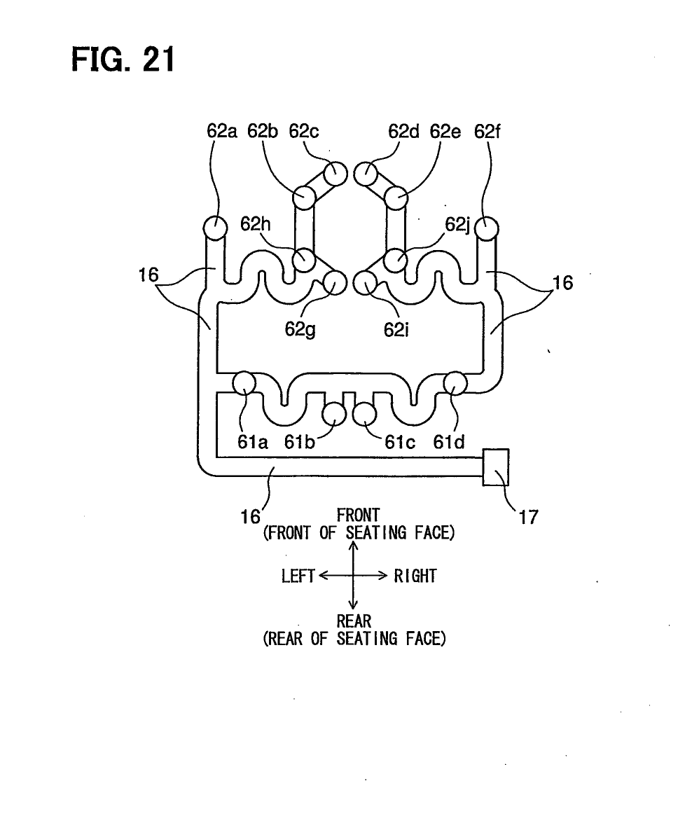

In the third embodiment, the opposed electrodes 62b, 62c, 62i, 62j, 62d, 62e, 62g, and 62h in the third contact pressure sensor group G3 are arranged such that a line segment connecting the opposed electrodes 62b, 62c, 62i, and 62j intersects with a line segment connecting the opposed electrodes 62d, 62e, 62g, and 62h (see FIG. 19). Alternatively, these opposed electrodes may be arranged in a different way. For example, as shown in FIG. 21, these opposed electrodes may be arranged in such a way that a line segment connecting the opposed electrodes 62b, 62h is parallel to a line segment connecting the opposed electrodes 62e, 62j. Alternatively, these opposed electrodes may be arranged in such a way that a line segment connecting the opposed electrodes 62b, 62c, a line segment connecting the opposed electrodes 62d, 62e, a line segment connecting the opposed electrodes 62g, 62h, and a line segment connecting the opposed electrodes 62i, 62j intersect with each other. In other words, the respective opposed electrodes 62 of the third contact pressure sensor group G3 may be arranged in an octagon shape. In these arrangements also, the same advantages are achievable.

The present disclosure has various aspects. For example, according to a first aspect, an occupant detection sensor for detecting a seating state of an occupant on a seat can be configured as follows. The occupant detection sensor comprises a contact pressure sensor section, an electrostatic sensor section, a capacitance measuring section, and an occupant distinguishing section. The contact pressure sensor section includes one or more pairs of opposed electrodes arranged approximately parallel to a seating face part of the seat. The pair of opposed electrodes is opposed to each other with a predetermined interval therebetween. The electrostatic sensor section includes a main electrode arranged approximately parallel to the seating face part of the seat and a guard electrode arranged between the main electrode and a seat frame. The guard electrode and the main electrode having a same electric potential. The capacitance measuring section measures a first capacitance generated between the opposed electrodes and a second capacitance generated between the main electrode and ground. The occupant distinguishing section distinguishes the seating state of the occupant based on the first capacitance and the second capacitance.

According to this configuration, since the occupant distinguishing section distinguishes the seating state of the occupant on the basis of the first capacitance and the second capacitance, it becomes possible to correctly distinguish the seating state of the occupant.

In the above, “the seating face part of the seat” refers to a portion within a predetermined range including a seating face (that is, obverse face) of the seat. For example, the seating face part may range from an obverse face of the seat to a top of a cushion pad. As for the “opposed electrodes”, there is no limitation to planar shape and thickness. The phrase “approximately parallel of the seating face” includes “parallel to the seating face of the seat” and “non-parallel to the seating face while angle to the seating face is being within a given angle range”. The term “main” of “main electrode” and “sub” of “sub electrode” are used to distinguish from each other. The “ground” is also called “body earth”. Any member having a constant electric potential (GND potential, which is not always set to 0 V) can be the “ground”. For example, the seat frame, a conductive member (specifically, a conductive wire) in the seat, or a vehicle body can act as the “ground”. The “seat frame” refers to a frame forming a framework of the seat. The “seating state of the occupant” refers to distinguishable arbitrary states. The “seating state of the occupant” may indicate whether the occupant is seated or not seated, whether the occupant is an adult of small build, an adult of large build, an infant etc., or the like.

The above occupant detection sensor may be configured as follows. When load of the occupant seated on the seat is applied, a distance between the opposed electrodes decreases. As the distance between the opposed electrodes decreases, the first capacitance increases. According to this configuration, based on the first capacitance variable in the above way, the occupant distinguishing section can correctly distinguish the seating state of the occupant

The above occupant detection sensor may be configured as follows. The electrostatic sensor section further includes a sub electrode arranged separately from the main electrode in a plane direction. The capacitance measuring section measures a third capacitance generated between the sub electrode and the main electrode. The occupant distinguishing section distinguishes the seating state of the occupant at least based on the first capacitance, the second capacitance, and the third capacitance, which are measured by the capacitance measuring section. According to this configuration, since the seating state of the occupant can be distinguished based on the first capacitance, the second capacitance and the third capacitance, various modes (various seating states) can be distinguished. Further, because of consideration of the third capacitance, a false detection caused by a disturbance can be minimized.

The above occupant detection sensor may be configured as follows. The contact pressure sensor section and the electrostatic sensor section are integrated by use of an insulating planar member that is arranged in common between the main electrode and the guard electrode and between the opposed electrodes. According to this configuration, a manufacturing process can be simplified and a manufacturing cost can be reduced as compared with a case where individual planar members are used for respective sensor sections.

The above occupant detection sensor may be configured as follows. The contact pressure sensor section and the electrostatic sensor section are integrated by further use of a first covering member that covers both of the main electrode and one of the opposed electrodes. According to this configuration, since the first covering member can play a role of protecting the main electrode and the opposed electrodes (one of the opposed electrodes), electrode durability improves.

The above occupant detection sensor may be configured as follows. The contact pressure sensor section and the electrostatic sensor section are integrated by further use of a second covering member that covers both of the guard electrode and the other of the opposed electrodes. According to this configuration, since the second covering member plays a role of protecting the guard electrode and the opposed electrodes (the other of the opposed electrodes), the electrode durability further improves.

The above occupant detection sensor may be configured as follows.

The second covering member is made of (i) a first material for covering the guard electrode and (ii) a second material for covering the other of the opposed electrodes. The first material is different from the second material. Specifically, since the electrodes cannot certainly be protected in some cases depending on the material (quality of material, substance), different materials are used to protect both electrodes certainly. Thus, it is possible to certainly protect the guard electrode and the opposed electrodes (other electrode) and to improve the durability of these electrodes. Here, as for “the first material” and “the second material”, any insulating material capable of covering the guard electrode and the opposed electrodes (other electrode) can be used. For example, a combination of use of a resist coat for the first material and a film for the second material may be employed. Alternatively, a combination of use of the film for the first material and the resist coat for the second material may be employed.

The above occupant detection sensor may be configured as follows. The main electrode and the guard electrode of the electrostatic sensor section are formed on one face side of the planar member and the other face side of the planar member, respectively, so that position of the main electrode corresponds to that of the guard electrode. According to this configuration, since it is sufficient to form the respective electrodes on the one face side and the other face side of the planar member, it is possible to simplify the manufacturing process. Additionally, it is possible to surely prevent noises from entering the main electrode from a guard electrode side.

The above occupant detection sensor may be configured as follows. The one of the opposed electrodes and the other of the opposed electrodes are formed on one face side of the planar member and the other face side of the planar member, respectively, so that position of the one of the opposed electrodes corresponds to that of the other of the opposed electrodes. According to this configuration, it is sufficient to form the pair of opposed electrodes on the one face side and the other face side of the planar member, respectively. Therefore, it is possible to simplify the manufacturing process, and additionally, it is possible to surely generate the first capacitance between the electrodes.

The above occupant detection sensor may be configured as follows. At least one of the planar member, the first covering member and the second covering member is made from an insulating film. According to this configuration, because of the use of the film, the contact pressure sensor section and the electrostatic sensor section as a whole can be thin. It should be noted that any material having an insulating property can be used for the “film”.

The above occupant detection sensor may be configured as follows. The contact pressure sensor section and the electrostatic sensor section are separated from each other and are provided with a single pad member. According to this configuration, the contact pressure sensor section and the electrostatic sensor section can be arranged on a face or a depressed portion of the single pad member. Thus, the contact pressure sensor section and the electrostatic sensor section can be integrated as a whole. As a result, the manufacturing process can be simplified and the manufacturing cost can be reduced as compared with a case where individual pad members are used for the respective sensor sections. It should be noted that any material having a cushion property can be used for “the pad member”.

The above occupant detection sensor may be configured as follows. The contact pressure sensor section and the electrostatic sensor section are provided with the pad member in one of: (i) a first structure in which the contact pressure sensor section and the electrostatic sensor section are on a same face of the pad member; (ii) a second structure in which the contact pressure sensor section and the electrostatic sensor section are separated and are on opposite surfaces of the pad member, respectively; and (iii) a third structure in which one of the contact pressure sensor section and the electrostatic sensor section is on one face of the pad member, and the other of the contact pressure sensor section and the electrostatic sensor section is inside the pad member. Even if any of the structures is employed, the contact pressure sensor section, the electrostatic sensor section and the pad member can be integrated with each other. Therefore, the manufacturing process can be simplified.

The above occupant detection sensor may be configured as follows. At a portion between the opposed electrodes, the planar member defines a hole having a predetermined shape. According to this configuration, a space (air gap) for storing electric charges can be secured between the opposed electrodes. Thus, the first capacitance can be certainly generated between the opposed electrodes. It should be noted that any planar shape or any cubic shape can be employed as the “predetermined shape”. The “hole” refers to not only a through hole but also a non-through hole (in other words, a depressed portion).

The above occupant detection sensor may be configured as follows. The opposed electrodes, respectively, have facing surfaces, which face each other. An insulating film is arranged on the facing surface of either one or both of the opposite electrodes. According to this configuration, it is possible to form a space for storing the electric charges between the pair of opposed electrodes and to prevent a trouble that both electrodes are brought into contact with each other (in other words, short-circuited) to make the capacitance indefinite (infinitely great). It should be noted that a film having an insulating property can be used for the “insulating film”, irrespective of a material of the film.

The above occupant detection sensor may be configured as follows. An insulating body is interposed between the hole of the planar member and the other of the opposed electrodes. According to this configuration, the hole of the planar member act as a space for storing the electric charges, while the insulating body prevents a trouble that both electrodes are brought into contact with each other to make the capacitance indefinite. It should be noted that any member (including a film) having an insulating property can be used for the “insulating body”.

The above occupant detection sensor may be configured as follows. The capacitance measuring section performs capacitance measurement based on a value of current flowing between the electrodes. According to this configuration, since there is a given relationship between the current and the capacitance, current value measurement enables reliable measurement of the capacitance (e.g., the first capacitance, the second capacitance, and the third capacitance).

The above occupant detection sensor may be configured as follows. The occupant distinguishing section distinguishes whether the occupant is an adult of small build or an adult of average build, by determining whether or not the first capacitance measured by the capacitance measuring section is greater than or equal to a threshold. According to this configuration, by determining whether or not the first capacitance generated between the opposed electrodes is greater than or equal to the threshold, it is possible to determine whether the occupant is an adult of small build or an adult of average build.

The above occupant detection sensor may be configured as follows. The one or more pairs of opposed electrodes of the contact pressure sensor section is a plurality of pairs of opposed electrodes including a first group of multiple pairs of opposed electrodes and a second group of multiple pairs of opposed electrodes. The first group of multiple pairs of opposed electrodes is a first contact pressure sensor group. The second group of multiple pairs of opposed electrodes is a second contact pressure sensor group. The first contact pressure sensor group and the second contact pressure sensor group are arranged in a front-rear direction of the seat. A second electrode total area, which is defined as a sum total of areas of the opposed electrodes in the second contact pressure sensor group, is larger than a first electrode total area, which is defined as a sum total of areas of the opposed electrodes of the first contact pressure sensor group. According to this configuration, even when the seating posture of the occupant is shifted in the front-rear direction of the seat, the seating state of the occupant can be distinguished correctly.

The above occupant detection sensor may be configured as follows. The first contact pressure sensor group is arranged at a rear portion of the seating face part of the seat. The second contact pressure sensor group is arranged at a center portion of the seating face part of the seat. According to this configuration, when the occupant is deeply seated, the first contact pressure sensor group can detect the seating state of the occupant. When the occupant is shallowly seated, the second contact pressure sensor group can detect the seating state of the occupant. Thus, the seating state of the occupant can be distinguished correctly.

The above occupant detection sensor may be configured as follows. At least one of a number of rows, a number of columns and a total number of opposed electrodes in the second contact pressure sensor group is larger than that of opposed electrodes in the first contact pressure sensor group. According to this configuration, it becomes to correctly distinguish the seating state of the occupant.

The above occupant detection sensor may be configured as follows. Some of the opposed electrodes included in either one of or both of the first contact pressure sensor group and the second contact pressure sensor group are arranged in three or more rows or in three or more columns at approximately equal intervals. In the above, “approximately equal intervals” refers to not only “equal intervals” but also “indeterminate intervals containing an error within an acceptable range”. According to this configuration, since the opposed electrodes in the first contact pressure sensor group and/or in the second contact pressure sensor group are arranged at approximately equal intervals, the seating state of the occupant can be correctly distinguished based on the capacitances of the respective opposed electrodes measured by the capacitance measuring section.

The above occupant detection sensor may be configured as follows. At least one of the first contact pressure sensor group and the second contact pressure sensor group is equipped with a stretch portion. The stretch portion is a stretchable signal line having a non-straight shape and electrically connects the opposed electrodes. According to this configuration, the stretch portion is stretchable in response to the load, which is variable according to the seating state of the occupant such as the occupant being seated, the occupant leaving the seat, the occupant being reseated, and the like. Thus, even if the load varies due to the occupant, a break in the signal line (including a trouble that the occupant cannot be detected by the occupant detection sensor; the same applies to the following) can be prevented.

The above occupant detection sensor may be configured as follows. The stretch portion is located between a first set of the pairs of opposed electrodes and a second set of the pairs of opposed electrodes. The first set of the pairs of opposed electrodes is at a center portion of the seating face part. The second set of the pairs of opposed electrodes is closer to a left end or a right end of the seating face part than the first set of the pairs of opposed electrodes is. According to this configuration, the stretch portion is stretchable in the left-right direction of the seating face. Thus, even when the load varies due to the occupant, the breaking of the signal line can be reliably prevented.

The above occupant detection sensor may be configured as follows. A part of the opposed electrodes in the second contact pressure sensor group is arranged in a center region of the seating face part of the seat. A third electrode area, which is defined as a sum total of areas of the part of the opposed electrodes in the second contact pressure sensor group, is larger than a fourth electrode area. The fourth electrode area is defined as a sum total of (i) areas of the rest of opposed electrodes in the second contact pressure sensor group and (ii) areas of the opposed electrodes in the first contact pressure sensor group. According to this configuration, even when the occupant is deeply seated or shallowly seated, the seating state can be correctly distinguished with use of the part of the opposed electrodes in the second contact pressure sensor group.

The above occupant detection sensor may be configured as follows. With respect to a left-to-right direction of the seating face part, a most-right pair and a most-left pair of the multiple pairs of the opposed electrodes in the second contact pressure sensor group are located outward than a most-right pair and a most-left pair of the multiple pairs of the opposed electrodes in the first contact pressure sensor group. In typical cases, the hip of the occupant is on a back-side portion (backrest side) of the seat. The hip or the thigh of the occupant is on a front-side portion (away from the backrest side). According to this configuration, the seating state of the occupant can be correctly distinguished irrespective of the seating position of the occupant.

The above occupant detection sensor may be configured as follows. The second contact pressure sensor group detects a hip or a thigh of the occupant and the first contact pressure sensor group detects the hip of the occupant. According to this configuration, when the occupant is deeply seated, the first contact pressure sensor group can detect the hip of the occupant and the second contact pressure sensor group can detect the thigh of the occupant. When the occupant is shallowly seated, the second contact pressure sensor group can detect the hip of the occupant. Thus, the seating state of the occupant can be correctly distinguished irrespective of the seating position of the occupant.

According a second aspect of the present disclosure, a method of manufacturing an occupant detection sensor which detects a seating state of an occupant on a seat is provided. The method comprises: forming an insulating film, which is to be on a facing surface of either or both of a pair of opposed electrodes which are opposed to each other with a predetermined interval therebetween so that the opposed electrodes, respectively, have the facing surfaces, which face each other; making a hole at a predetermined position in an insulating planar member; forming a main electrode and one of the opposed electrodes, wherein the main electrode is to be approximately parallel to the seating face part of the seat; forming a guard electrode and the other of the opposed electrodes, wherein the guard electrode is to be between the seating face part and a seat frame; covering the main electrode and the one of the opposed electrodes with a first covering member; and covering the guard electrode and the other of the opposed electrodes with a second covering member.

According to the occupant detection sensor manufactured by the above method, the main electrode and the one of the opposed electrodes are on one side of the planer member, and additionally, the guard electrode and the other of the opposed electrodes are on the other side of the planer member. The planer member or the hole, each of which can be used for storing the electric charges, is between the corresponding electrodes. Thus, the capacitances can be reliably generated between the corresponding electrodes. Furthermore, since these electrodes are protected by the first covering member and the second covering member, durability improves.

In forming the main electrode and the one of the opposed electrodes, a sub electrode separated from main electrode in a plane direction may be further formed. According to this method, it is possible to generate a third capacitance between the sub electrode and the main electrode, and it possible to distinguish various modes (various seating sates).

In the above method, covering the guard electrode and the other of the opposed electrodes with a second covering member may include (i) covering the guard electrode with a first material and (ii) covering the other of the opposed electrodes with a second material different from the first material. According to this method, it is possible to reliably protect the guard electrode and the opposed electrodes (other of the opposed electrodes), and it is possible to improve the durability of these electrodes.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. An occupant detection sensor for detecting a seating state of an occupant on a seat, the occupant detection sensor comprising:
a contact pressure sensor section including one or more pairs of opposed electrodes arranged approximately parallel to a seating face part of the seat, each pair of opposed electrodes being opposed to each other with a predetermined interval therebetween;
an electrostatic sensor section including a main electrode and a guard electrode, the main electrode being arranged approximately parallel to the seating face part of the seat, the guard electrode being arranged between the main electrode and a seat frame, the guard electrode and the main electrode having a same electric potential;
a capacitance measuring section for measuring a first capacitance generated between the opposed electrodes and a second capacitance generated between the main electrode and ground; and
an occupant distinguishing section for distinguishing the seating state of the occupant based on the first capacitance and the second capacitance.

2. The occupant detection sensor according to claim 1, wherein:
when load of the occupant seated on the seat is applied, a distance between the opposed electrodes decreases; and
as the distance between the opposed electrodes decreases, the first capacitance increases.

3. The occupant detection sensor according to claim 1, wherein:
the electrostatic sensor section further includes a sub electrode arranged separately from the main electrode in a plane direction;
the capacitance measuring section measures a third capacitance generated between the sub electrode and the main electrode; and
the occupant distinguishing section distinguishes the seating state of the occupant, at least based on the first capacitance, the second capacitance, and the third capacitance, which are measured by the capacitance measuring section.

4. The occupant detection sensor according to claim 1, wherein:
the contact pressure sensor section and the electrostatic sensor section are integrated by use of an insulating planar member that is arranged in common between the main electrode and the guard electrode and between the opposed electrodes.

5. The occupant detection sensor according to claim 4, wherein
the contact pressure sensor section and the electrostatic sensor section are integrated by further use of a first covering member that covers both of the main electrode and one of the opposed electrodes.

6. The occupant detection sensor according to claim 5, wherein
the contact pressure sensor section and the electrostatic sensor section are integrated by use of a second covering member that covers both of the guard electrode and the other of the opposed electrodes.

7. The occupant detection sensor according to claim 6, wherein
the second covering member is made of
a first material for covering the guard electrode and
a second material for covering the other of the opposed electrodes; and
the first material is different from the second material.

8. The occupant detection sensor according to claim 4, wherein:
the main electrode and the guard electrode of the electrostatic sensor section are formed on one face side of the planar member and the other face side of the planar member, respectively, so that position of the main electrode corresponds to that of the guard electrode.

9. The occupant detection sensor according to claim 6, wherein
the one of the opposed electrodes and the other of the opposed electrodes are formed on one face side of the planar member and the other face side of the planar member, respectively, so that position of the one of the opposed electrodes corresponds to that of the other of the opposed electrodes.

10. The occupant detection sensor according to claim 6, wherein
at least one of the planar member, the first covering member and the second covering member is made from an insulating film.

11. The occupant detection sensor according to claim 1, wherein
the contact pressure sensor section and the electrostatic sensor section are separated from each other and are provided with a single pad member.

12. The occupant detection sensor according to claim 11, wherein
the contact pressure sensor section and the electrostatic sensor section are provided with the pad member in one of:
a first structure in which the contact pressure sensor section and the electrostatic sensor section are on a same face of the pad member;
a second structure in which the contact pressure sensor section and the electrostatic sensor section are on opposite surfaces of the pad member, respectively; and
a third structure in which one of the contact pressure sensor section and the electrostatic sensor section is on one face of the pad member, and the other of the contact pressure sensor section and the electrostatic sensor section is inside the pad member.

13. The occupant detection sensor according to claim 6, wherein
at a portion between the opposed electrodes, the planar member defines a hole having a predetermined shape.

14. The occupant detection sensor according to claim 1, wherein:
the opposed electrodes, respectively, have facing surfaces, which face each other; and
an insulating film is arranged on the facing surface of either one or both of the opposed electrodes.

15. The occupant detection sensor according to claim 13, wherein
an insulating body is interposed between the hole of the planar member and the other of the opposed electrodes.

16. The occupant detection sensor according to claim 1, wherein
the capacitance measuring section performs capacitance measurement based on a value of current flowing between the electrodes.

17. The occupant detection sensor according to claim 16, wherein
the occupant distinguishing section distinguishes whether the occupant is an adult of small build or an adult of average build, by determining whether or not the first capacitance measured by the capacitance measuring section is greater than or equal to a threshold.

18. The occupant detection sensor according to claim 1, wherein:
the one or more pairs of opposed electrodes of the contact pressure sensor section is a plurality of pairs of opposed electrodes including a first group of multiple pairs of opposed electrodes and a second group of multiple pairs of opposed electrodes;
the first group of multiple pairs of opposed electrodes is a first contact pressure sensor group;
the second group of multiple pairs of opposed electrodes is a second contact pressure sensor group;
the first contact pressure sensor group and the second contact pressure sensor group are arranged in a front-rear direction of the seat; and
a second electrode total area, which is defined as a sum total of areas of the opposed electrodes in the second contact pressure sensor group, is larger than a first electrode total area, which is defined as a sum total of areas of the opposed electrodes of the first contact pressure sensor group.

19. The occupant detection sensor according to claim 18, wherein:
the first contact pressure sensor group is arranged at a rear portion of the seating face part of the seat; and
the second contact pressure sensor group is arranged at a center portion of the seating face part of the seat.

20. The occupant detection sensor according to claim 18, wherein
at least one of a number of rows, a number of columns and a total number of opposed electrodes in the second contact pressure sensor group is larger than that of opposed electrodes in the first contact pressure sensor group.

21. The occupant detection sensor according to claim 18, wherein
some of the opposed electrodes included in either one of or both of the first contact pressure sensor group and the second contact pressure sensor group are arranged in three or more rows or in three or more columns at approximately equal intervals.

22. The occupant detection sensor according to claim 18, wherein:
at least one of the first contact pressure sensor group and the second contact pressure sensor group is equipped with an stretch portion; and
the stretch portion is a stretchable signal line having a non-straight shape and electrically connects the opposed electrodes.

23. The occupant detection sensor according to claim 22, wherein:
the stretch portion is located between a first set of the pairs of opposed electrodes and a second set of the pairs of opposed electrodes;
the first set of the pairs of opposed electrodes is at a center portion of the seating face part; and
the second set of the pairs of opposed electrodes is closer to a left end or a right end of the seating face part than the first set of the pairs of opposed electrodes is.

24. The occupant detection sensor according to claim 18, wherein:
a part of the opposed electrodes in the second contact pressure sensor group is arranged in a center region of the seating face part of the seat;
a third electrode area, which is defined as a sum total of areas of the part of the opposed electrodes in the second contact pressure sensor group, is larger than a fourth electrode area; and
the fourth electrode area is defined as a sum total of
areas of the rest of opposed electrodes in the second contact pressure sensor group and
areas of the opposed electrodes in the first contact pressure sensor group.

25. The occupant detection sensor according to claim 18, wherein:
with respect to a left-to-right direction of the seating face part, a most-right pair and a most-left pair of the multiple pairs of the opposed electrodes in the second contact pressure sensor group are located outward than a most-right pair and a most-left pair of the multiple pairs of the opposed electrodes in the first contact pressure sensor group.

26. The occupant detection sensor according to claim 18, wherein
the second contact pressure sensor group detects a hip or a thigh of the occupant and the first contact pressure sensor group detects the hip of the occupant.

27. A method of manufacturing an occupant detection sensor which detects a seating state of an occupant on a seat, the method comprising:
forming an insulating film, which is to be on a facing surface of either or both of a pair of opposed electrodes which are opposed to each other with a predetermined interval therebetween so that the opposed electrodes, respectively, have the facing surfaces, which face each other;
making a hole at a predetermined position in an insulating planar member;
forming a main electrode and one of the opposed electrodes, wherein the main electrode is to be approximately parallel to the seating face part of the seat;
forming a guard electrode and the other of the opposed electrodes, wherein the guard electrode is to be between the seating face part and a seat frame;
covering the main electrode and the one of the opposed electrodes with a first covering member; and
covering the guard electrode and the other of the opposed electrodes with a second covering member.

28. The method of manufacturing an occupant detection sensor according to claim 27, wherein
in forming the main electrode and the one of the opposed electrodes, a sub electrode separated from main electrode in a plane direction is formed.

29. The method of manufacturing an occupant detection sensor according to claim 27, wherein
covering the guard electrode and the other of the opposed electrodes with a second covering member includes
covering the guard electrode with a first material and
covering the other of the opposed electrodes with a second material different from the first material.
